(19) United States
(12) Patent Application Publication
(10) Pub. No.: US 2026/0090126 A1
(43) Pub. Date: Mar. 26, 2026

(54) IMAGE SENSOR

(71) Applicant: Samsung Electronics Co., Ltd., Suwon-si (KR)

(72) Inventors: Kwang-Min LEE, Suwon-si (KR); Shili QUAN, Suwon-si (KR); Kyounghwan KIM, Suwon-si (KR); Sungeun LEE, Suwon-si (KR)

(73) Assignee: Samsung Electronics Co., Ltd., Suwon-si (KR)

(21) Appl. No.: 19/086,345

(22) Filed: Mar. 21, 2025

(30) Foreign Application Priority Data
Sep. 25, 2024 (KR) 10-2024-0129543

(51) Int. Cl. H10F 39/00; H10F 39/18

(52) U.S. Cl. CPC H10F 39/811; H10F 39/182; H10F 39/807

(57) ABSTRACT

An image sensor may include a substrate, a dummy isolation pattern, and a wiring layer on the substrate. The substrate may include a pixel area with pixels, a power region outside the pixel area, photoelectric converters in the substrate and corresponding to the pixels, and a ground portion in the power region and surrounded by the dummy isolation pattern. The ground portion may be electrically insulated from the photoelectric converters by the dummy isolation pattern. The wiring layer may include first and second connection wiring structures. the first connection wiring structure may overlap the ground portion in a vertical direction and may be configured to receive a power voltage. The second connection wiring structure may vertically overlap the photoelectric converters and may electrically connect the substrate and the first connection wiring structure. The first connection wiring structure may include a first contact electrode electrically connected to the ground portion.

### CROSS-REFERENCE TO RELATED APPLICATION

This application claims priority to and the benefit of Korean Patent Application No. 10-2024-0129543 filed in the Korean Intellectual Property Office on Sep. 25, 2024, the entire contents of which are incorporated herein by reference.

### BACKGROUND

### 1. Field

The present disclosure relates to an image sensor.

### 2. Description of the Related Art

CMOS image sensors are solid-state image sensing devices using complementary metal-oxide semiconductors (CMOSs). As compared to CCD image sensors with high-voltage analog circuits, CMOS image sensors may have lower manufacturing costs and lower power consumption due to the small sizes of elements. CMOS image sensors mainly may be mounted in home appliances including portable devices such as smart phones, digital cameras, etc.

A pixel array constituting a CMOS image sensor includes a photodiode in each pixel. The photodiodes may generate electrical signals that vary depending on the amounts of incident light, and the CMOS image sensor may synthesize an image by processing the electrical signals.

Recently, in response to the demand for high-definition images, pixels that constitute CMOS image sensors are being required to be downsized. As this demand for downsizing increases, it may be critical to effectively reduce occurrence of dark current and white spots.

### SUMMARY

The present disclosure relates to an image sensor with improved reliability.

An image sensor according to an embodiment may include a first chip including a first surface; and a second chip on the first chip and including a second surface, the second surface of the second chip facing the first surface of the first chip. The first chip may further include a first connection pad on the first surface of the first chip. The second chip may further include transistors and a second connection pad electrically connected to the transistors. The second connection pad may be on the second surface of the second chip. The first connection pad and the second connection pad may be electrically connected to each other. The first chip may further include a substrate, a plurality of photoelectric converters in the substrate and corresponding to a plurality of pixels in a pixel area of the substrate, a ground portion in a peripheral area of the substrate, a dummy isolation pattern surrounding the ground portion and passing through the substrate, and a wiring layer. The substrate may include a third surface and a fourth surface opposite each other. The wiring layer may include a first connection wiring structure. The first connection wiring structure may be on the third surface of the substrate in the peripheral area and may be electrically connected to the second connection pad. The first connection wiring structure may include a first contact electrode electrically connected to the ground portion in the peripheral area.

An image sensor according to an embodiment may include a substrate including a pixel area with a plurality of pixels, a power region outside the pixel area and configured to receive a power voltage, a plurality of photoelectric converters in the substrate and corresponding to the plurality of pixels, and a ground portion in the power region of the substrate; a dummy isolation pattern surrounding the ground portion and passing through the substrate; and a wiring layer on the substrate. The ground portion may be electrically insulated from the plurality of photoelectric converters by the dummy isolation pattern. The wiring layer may further include a first connection wiring structure and a second connection wiring structure. The first connection wiring structure may overlap the ground portion in a vertical direction. The first connection wiring structure may be configured to receive a power voltage. The second connection wiring structure may overlap the plurality of photoelectric converters in the vertical direction. The second connection wiring structure may electrically connect the substrate and the first connection wiring structure. The first connection wiring structure may include a first contact electrode. The first contact electrode may be electrically connected to the ground portion.

An image sensor according to an embodiment may include a first chip including a first surface; and a second chip on the first chip and including a second surface, the second surface of the second chip facing the first surface of the first chip. The first chip may further include a first connection pad on the first surface of the first chip. The second chip may further include transistors and a second connection pad electrically connected to the transistors. The second connection pad may be on the second surface of the second chip. The first connection pad and the second connection pad may be electrically connected to each other. The first chip may further include a substrate, a plurality of photoelectric converters in the substrate and corresponding to a plurality of pixel in a pixel area of the substrate, a pixel isolation pattern between the plurality of photoelectric converters, a ground portion in a peripheral area of the substrate, a dummy isolation pattern surrounding the ground portion and passing through the substrate, a wiring layer, a micro lens layer, and a first connection wiring structure. The substrate may include a third surface and a fourth surface facing opposite each other. The dummy isolation pattern may be spaced apart from the pixel isolation pattern. The micro lens layer may be on the fourth surface of the substrate in the pixel area. The first connection wiring structure may be on the third surface of the substrate in the peripheral area and electrically connected to the second connection pad. The first connection wiring structure may include a plurality of connection wiring lines, a plurality of vias connecting the plurality of connection wiring lines, and a first contact electrode between the plurality of connection wiring lines and the ground portion. The first connection wiring may be electrically connected to the ground portion.

According to the embodiments, a portion of the wiring layer may be electrically connected to a ground portion of a power region such that charge can be released into the ground portion. Accordingly, the reliability of the image sensor can improve.

### BRIEF DESCRIPTION OF THE DRAWINGS

FIG. 1 is a block diagram of an image sensor according to an embodiment.

FIG. 2 is a circuit diagram of a pixel array of the image sensor according to the embodiment.

FIG. 3 is a cross-sectional view illustrating a pixel area and an optical black area of the image sensor according to the embodiment.

FIGS. 4 to 6 are cross-sectional views illustrating the pixel area and peripheral area of the image sensor according to the embodiment.

FIG. 7 is a plan view illustrating a power region of the image sensor according to the embodiment, as an example.

FIG. 8 is a cross-sectional view illustrating the pixel area and peripheral area of the image sensor according to the embodiment.

FIG. 9 is a cross-sectional view illustrating a power region of an image sensor according to some embodiments.

FIG. 10 is a plan view illustrating the power region of the image sensor according to some embodiments, as an example.

FIGS. 11 and 12 are cross-sectional views illustrating the power region of the embodiment of FIG. 10.

FIG. 13 is a plan view illustrating the power region of the image sensor according to some embodiments, as an example.

FIG. 14 is a cross-sectional view illustrating the power region of the embodiment of FIG. 13.

FIG. 15 is a plan view illustrating the power region of the image sensor according to some embodiments, as an example.

FIG. 16 is a plan view illustrating the power region of the image sensor according to some embodiments, as an example.

FIGS. 17 to 19 are cross-sectional views illustrating the power region of the embodiment of FIG. 15.

### DETAILED DESCRIPTION OF THE EMBODIMENTS

In the following detailed description, some example embodiments are shown and described. However, example embodiments may be implemented in various forms and are not limited to the presented embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but example embodiments are not limited thereto. In the drawings, the thickness of layers, films, panels, regions, etc., are exaggerated for clarity. In the drawings, for understanding and ease of description, the thickness of some layers and areas is exaggerated. The notion that elements are “substantially the same” may indicate that the element may be completely the same and may also indicate that the elements may be determined to be the same in consideration of errors or deviations occurring during a process.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, throughout this specification, unless explicitly described to the contrary, the word “comprise”, and variations such as “comprises” or “comprising”, will be understood to imply the inclusion of stated elements but not the exclusion of any other elements.

Further, throughout this specification, when it is referred to as “on a plane”, it means when a target part is viewed from above, and when it is referred to as “on a cross-section”, it means when the cross-section obtained by cutting a target part vertically is viewed from the side.

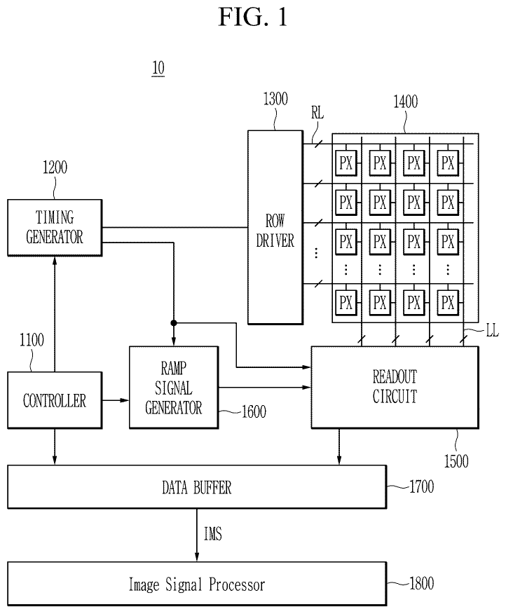

Hereinafter, an image sensor according to an embodiment will be described with reference to FIG. 1.

FIG. 1 is a block diagram of an image sensor according to an embodiment.

Referring to FIG. 1, an image sensor 10 according to an embodiment may include a controller 1100, a timing generator 1200, a row driver 1300, a pixel array 1400, a readout circuit 1500, a ramp signal generator 1600, a data buffer 1700, and an image signal processor 1800.

In the embodiment, the image signal processor 1800 may be positioned outside the image sensor 10.

The image sensor 10 may generate an image signal by converting light received from the outside into an electrical signal. The image signal (IMS) may be provided to the image signal processor 1800.

The image sensor 10 may be mounted in an electronic device having an image or light sensing function. For example, the image sensor 10 may be mounted in electronic devices such as cameras, smart phones, wearable devices, IoT (Internet of Things) devices, home appliances, tablet PCs (personal computers), personal digital assistants (PDAs), portable multimedia players (PMPs) navigation devices, drones, advanced drivers assistance systems (ADASs), etc. Also, the image sensor 10 may be mounted in electronic devices which are incorporated as components in vehicles, furniture, manufacturing equipment, doors, various measuring devices, etc.

The controller 1100 may generally control the individual constituent elements 1200, 1300, 1500, 1600, and 1700 included in the image sensor 10. The controller 1100 may control the operation timings of the individual constituent elements 1200, 1300, 1500, 1600, and 1700, using control signals.

In the embodiment, the controller 1100 may receive a mode signal indicating an imaging mode, from an application processor, and generally control the image sensor 10 on the basis of the received mode signal. For example, the application processor may determine an imaging mode of the image sensor 10 according to various scenarios such as the illumination in the imaging environment, the user's resolution setting, a sensed or learned state, etc., and provide the determined result as a mode signal to the controller 1100.

The controller 1100 may perform control such that a plurality of pixels PX of the pixel array 1400 outputs pixel signals according to the imaging mode, and the pixel array 1400 may output the pixel signals of the plurality of individual pixels PX or the pixel signals of some of the plurality of pixels PX, and the readout circuit 1500 may sample and process the pixel signals received from the pixel array 1400.

The timing generator 1200 may generate a signal which is a reference for the operation timings of the components of the image sensor 10. The timing generator 1200 may control timings of the row driver 1300, the readout circuit 1500, and the ramp signal generator 1600. The timing generator 1200 may provide a control signal to control the timings of the row driver 1300, the readout circuit 1500, and the ramp signal generator 1600.

The pixel array 1400 may include the plurality of pixels PX, and a plurality of row lines RL and a plurality of column lines LL that are connected to the plurality of pixels PX, respectively.

The plurality of pixels PX included in the pixel array 1400 may be arranged in a matrix. Each pixel PX may include a transfer transistor. Each pixel PX may further include a logic transistor.

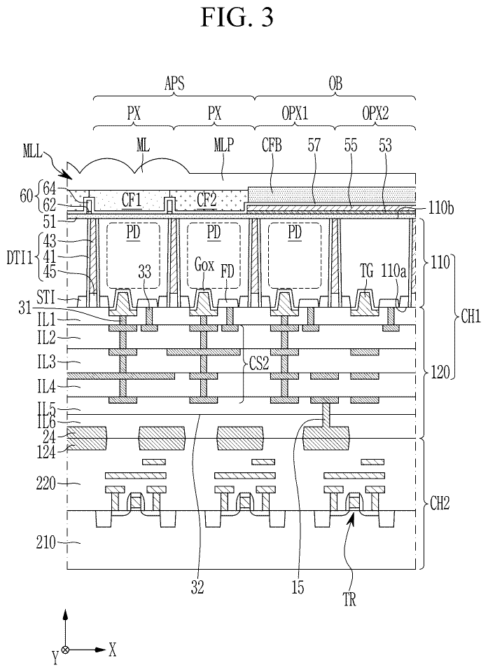

The logic transistor may be a reset transistor, a selection transistor, or a source follower transistor. The transfer transistor may include a transfer gate (reference symbol “TG” in FIG. 3). Each pixel PX may further include a photoelectric converter PD and a floating diffusion zone (reference symbol “FD” in FIG. 3). The logic transistors may be shared by a plurality of pixels PX.

The photoelectric converter PD may sense incident light from the outside, and convert the incident light into electrical signals according to the amounts of light, i.e., into a plurality of analog pixel signals. The photoelectric converter PD may include a photodiode, a photo transistor, a photogate, a pinned photodiode, or a combination thereof.

Also, the photoelectric converter PD may be a single-photon avalanche diode (SPAD) which is applied to a 3D sensor pixel. The levels of analog pixel signals which are output from the photoelectric converter PD may be proportional to the amounts of charge which are output from the photoelectric converter PD. In other words, the levels of analog pixel signals which are output from the photoelectric converter PD may be determined depending on the amount of light which enters the pixel array 1400.

The transfer transistor may transfer charge generated by the photoelectric converter (reference symbol “PD” in FIG. 3), to the floating diffusion zone (reference symbol “FD” in FIG. 3). The floating diffusion zone (reference symbol “FD” in FIG. 3) may receive and accumulate the charge generated by the photoelectric converter (reference symbol “PD” in FIG. 3). Depending on the amount of photoelectric charge accumulated in the floating diffusion zone (reference symbol “FD” in FIG. 3), the source follower transistor may be controlled.

The reset transistor may periodically reset the charge accumulated in the floating diffusion zone (reference symbol “FD” in FIG. 3). The drain electrode of the reset transistor may be connected to the floating diffusion zone (reference symbol “FD” in FIG. 3) and the source electrode thereof be connected to a power voltage. When the reset transistor is turned on, the power voltage connected to the source electrode of the reset transistor may be applied to the floating diffusion zone (reference symbol “FD” in FIG. 3). Therefore, when the reset transistor is turned on, the charge accumulated in the floating diffusion zone (reference symbol “FD” in FIG. 3) may be released, whereby the floating diffusion zone FD may be reset.

The source follower transistor including a source follower gate electrode may serve as a source follower buffer amplifier. The source follower transistor may amplify a potential change in the floating diffusion zone FD, and output the result to an output line Vₒᵤₜ.

The selection transistor including a selection gate electrode may select pixels PX to be read out, on a row-by-row basis. When the selection transistor is turned on, the power voltage VDD may be applied to the drain electrode of the source follower transistor.

The plurality of row lines RL may extend in a first direction, and be connected to pixels PX arranged along the first direction. For example, a control signal that is output from the row driver 1300 to a row line RL may be transferred to the gates of the transistors of a plurality of pixels PX connected to the corresponding row line RL.

Each column line LL may extend in a second direction intersecting the first direction, and be connected to a plurality of pixels PX arranged along the second direction. A plurality of pixel signals that is output from the plurality of pixels PX may be transferred to the readout circuit 1500 through the plurality of column lines LL.

On the pixel array 1400, a color filter layer and a micro lens layer may be positioned. The micro lens layer may include a plurality of micro lenses, and at least one pixel PX corresponding to each of the plurality of micro lenses may be positioned.

The color filter layer may include color filters of red, green, blue, etc. For example, with respect to one pixel PX, a color filter of one color may be positioned between the pixel PX and a micro lens corresponding thereto.

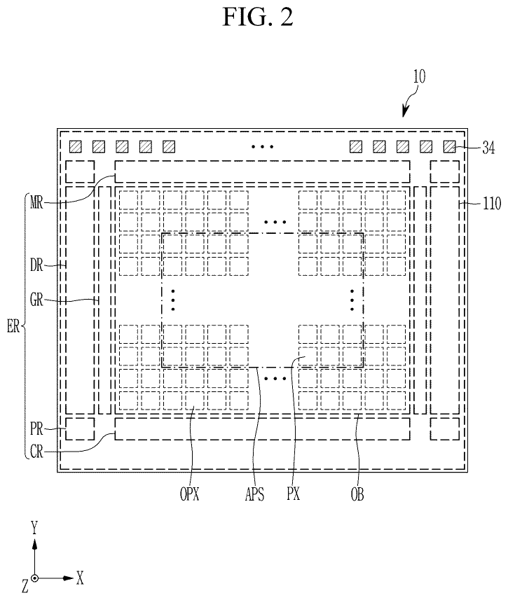

The row driver 1300 may generate a driving signal for driving the pixel array 1400, in response to a control signal from the timing generator 1200, and provide the driving signal to the plurality of pixels PX of the pixel array 1400 through the plurality of row lines RL. In the embodiment, the row driver 1300 may provide the driving signal to a plurality of pixels PX through a drive region (reference symbol “DR” in FIG. 2).

In the embodiment, the row driver 1300 may control the pixels PX in row line units, such that the pixels sense incident light. Each row line unit may include at least one row line RL. For example, the row driver 1300 may provide a driving signal including a transfer signal, a reset signal, a selection signal, and the like to the pixel array 1400.

The readout circuit 1500 may convert pixel signals (or electrical signals) received from pixels PX connected to a selected row line RL among the plurality of pixels PX, into pixel values indicating the amounts of light, in response to a control signal from the timing generator 1200. The readout circuit 1500 may convert pixel signals output through corresponding column lines LL into pixel values. For example, the readout circuit 1500 may convert pixel signals into pixel values by comparing the pixel signals with ramp signals. Pixel values may be image data items, each of which has a plurality of bits. Specifically, the readout circuit 1500 may include a selector, a plurality of comparators, a plurality of counter circuits, etc.

The ramp signal generator 1600 may generate a reference signal and transmit it to the readout circuit 1500.

The ramp signal generator 1600 may include current sources, resistors, and capacitors. The ramp signal generator 1600 may adjust ramp voltage which is voltage to be applied to a ramp resistor by adjusting the current magnitude of a variable current source or the resistance value of a variable resistor. In this way, the ramp signal generator may generate a plurality of ramp signals which falls or rise at slopes determined depending on the current magnitudes of variable current sources or the resistance values of variable resistors.

The data buffer 1700 may store the pixel values of the plurality of pixels PX connected to the selected column line LL, received from the readout circuit 1500, and output the stored pixel values in response to an enable signal from the controller 1100.

The image signal processor 1800 may perform image signal processing on image signals received from the data buffer 1700. For example, the image signal processor 1800 may receive a plurality of image signals from the data buffer 1700, and synthesize the received image signals to generate one image.

The image sensor 10 according to the embodiment may further include a power supply unit which provides a power voltage to a pixel PX or a peripheral element for operating the pixel. The power supply unit may apply the power voltage to a pixel PX or the inside of a first substrate (reference symbol “110” in FIG. 3) where the pixel PX is positioned. For example, the power supply unit may apply the power voltage to a pixel PX or the inside of the first substrate (reference symbol “110” in FIG. 3) where the pixel PX is positioned through the power region (reference symbol “PR” in FIG. 2). The power voltage may be, for example, a voltage for driving a pixel PX, or a voltage for applying a voltage having a desired and/or alternatively predetermined magnitude to the first substrate (reference symbol “110” in FIG. 3). As an example, the power voltage may be a negative bias voltage. As another example, the power voltage may include a ground voltage.

Hereinafter, the image sensor according to the embodiment will be described with reference to FIGS. 2 and 3.

FIG. 2 is a circuit diagram of the pixel array of the image sensor according to the embodiment. FIG. 3 is a cross-sectional view illustrating a pixel area and an optical black area of the image sensor according to the embodiment.

Referring to FIGS. 2 and 3, the image sensor 10 according to the embodiment may include a first chip CH1 including a first connection pad 24, and a second chip CH2 including a second connection pad 124. In the embodiment, the image sensor may have a structure in which the first and second chips CH1 and CH2 are bonded. In other words, the first chip CH1 may be positioned on the second chip CH2.

The first chip CH1 may perform an image sensing function. The second chip CH2 may include circuits for driving the first chip CH1 or for processing and storing electrical signals generated by the first chip CH1. The first chip CH1 may include a first surface. The first surface of the first chip CH1 may refer to the lower surface of the first chip CH1. The first surface of the first chip CH1 may be a surface facing the second chip CH2.

The first chip CH1 of the image sensor according to the embodiment may include a first substrate 110 that includes a pixel area APS and a peripheral area ER, a pixel isolation pattern DTI1, a plurality of photoelectric converters PD positioned inside the first substrate 110 in the pixel area APS, a ground portion DD positioned inside the first substrate 110 in the peripheral area ER, a dummy isolation pattern DTI2 that surrounds the ground portion DD, and a wiring layer 120 positioned on one surface of the first substrate 110.

The first substrate 110 may include a front surface and a rear surface facing each other. Hereinafter, the front surface and the rear surface will be referred to as the third surface 110a and the fourth surface 110b, respectively. The fourth surface 110b of the first substrate 110 may be a light receiving surface which light enters.

The first substrate 110 may include the pixel area APS, an optical black area OB, and the peripheral area ER.

The optical black area OB and the peripheral area ER may be positioned at least one side of the pixel area APS. For example, as shown in FIG. 2, the optical black area OB and the peripheral area ER may be sequentially positioned on the outside of the pixel area APS, and the optical black area OB may surround the pixel area APS. In other words, the optical black area OB may be positioned between the pixel area APS and the peripheral area ER.

The peripheral area ER may include a power region PR, a drive region DR, a sampler region CR, a cap region MR, and a guard region GR. In the embodiment, the power region PR, the drive region DR, the sampler region CR, the cap region MR, and the guard region GR may be positioned apart from the pixel area APS and the optical black area OB.

The drive region DR, the sampler region CR, and the guard region GR may be positioned outside the optical black area OB. For example, the drive region DR may be positioned on opposite sides of the optical black area OB in a first direction (an X direction), and the sampler region CR may be positioned on one side of the optical black area OB in a second direction (a Y direction), and the guard region GR may be positioned on the other side of the optical black area OB in the second direction (the Y direction); however, the arrangement relationship of the drive region DR, the sampler region CR, and the guard region GR is not limited thereto.

In the embodiment, the drive region DR may refer to a region where wiring lines for providing a driving signal from the row driver (reference symbol “1300” in FIG. 1) to the plurality of pixels PX are positioned. Further, the sampler region CR may refer to a region where wiring lines for providing pixel signals received from the plurality of pixels PX to the readout circuit (reference symbol “1500” in FIG. 1) are positioned. The cap region MR may refer to a region where a driving signal which is provided to the plurality of pixels PX and/or noise which is present in pixel signals received from the plurality of pixels PX is decoupled. In the embodiment, in the cap region MR, a capacitor for decoupling noise may be included.

The power region PR may be positioned outside the optical black area OB. For example, a plurality of power regions PR may be provided, and be positioned at the edge of the optical black area OB. The plurality of power regions PR may be disposed so as to surround the optical black area OB; however, the present disclosure is not limited thereto. The power region PR may be positioned on opposite sides of the drive region DR in the second direction (the Y direction) and/or on opposite sides of the sampler region CR and the guard region GR in the first direction (the X direction); however, the present disclosure is not limited thereto.

In the embodiment, the power region PR may refer to a region where the power voltage is applied from the second chip CH2 to a pixel PX or the inside of the first substrate 110. For example, some of the plurality of power regions PR provided may be regions where a wiring line (for example, a first connection wiring structure CS1) for applying the power voltage to a pixel PX is provided. Some others of the plurality of power regions PR provided may be regions where a wiring line for applying the power voltage to the first substrate 110 is provided. In this case, to the first substrate 110, a negative bias voltage or a ground voltage may be applied. Accordingly, the power voltage applied from the second chip CH2 may be provided to a pixel PX or the first substrate 110 through the power region PR.

The guard region GR may be positioned outside the optical black area OB. For example, the guard region GR may be positioned on opposite sides of the optical black area OB in the first direction (the X direction); however, the present disclosure is not limited thereto. The guard region GR may function to block light or electrons, which may be generated by a specific circuit in the peripheral area ER, from penetrating into the pixel area APS and/or the optical black area OB.

Also, in the peripheral area ER of the image sensor 10 according to the embodiment, a region where conductive pads 34 are further positioned may be further included. The conductive pads 34 may be positioned outside the pixel area APS. For example, the conductive pads 34 may be positioned at the edge portion of the first substrate 110 and be positioned on one side of the cap region MR in the second direction (the Y direction); however, the arrangement of the conductive pads 34 is not limited thereto.

It has been described with reference to FIG. 2 that each of the power region PR, the drive region DR, the sampler region CR, the cap region MR, and the guard region GR is positioned outside the optical black area OB in the first direction (the X direction) and/or the second direction (the Y direction); however, this is an example, and the arrangement relationship of the power region PR, the drive region DR, the sampler region CR, the cap region MR, and the guard region GR may be variously changed.

The first substrate 110 may be, for example, a silicon single crystal wafer, a silicon epitaxial layer, or a silicon on insulator (SOI) substrate. The first substrate 110 may contain an impurity of a first conductivity type. The first substrate 110 may be doped with the impurity of the first conductivity type. For example, the impurity of the first conductivity type may be a p-type impurity such as aluminum (Al), boron (B), indium (In), and/or gallium (Ga).

Hereinafter, for ease of explanation, constituent elements of the pixel area APS and the optical black area OB will be mainly described.

The pixel isolation pattern DTI1 may be positioned inside the first substrate 110. The pixel isolation pattern DTI1 may be positioned inside the pixel area APS and the optical black area OB. The pixel isolation pattern DTI1 may pass through the first substrate 110. The pixel isolation pattern DTI1 may be frontside deep trench isolation (FDTI).

In the embodiment, the pixel isolation pattern DTI1 may completely pass through the first substrate 110. For example, each side surface of the pixel isolation pattern DTI1 may be in contact with the third surface 110a and fourth surface 110b of the first substrate 110. The upper surface of the pixel isolation pattern DTI1 and the fourth surface 110b of the first substrate 110 may be flat. However, the present disclosure is not limited thereto, and each upper surface of the pixel isolation pattern DTI1 may include a surface curved with respect to the fourth surface 110b of the first substrate 110.

In the embodiment, the pixel isolation pattern DTI1 may have a shape whose width decreases as it goes from the third surface 110a of the first substrate 110 toward the fourth surface 110b. In other words, the pixel isolation pattern DTI1 may have an inclined side surface. However, the present disclosure is not limited thereto, and the pixel isolation pattern DTI1 may have a shape whose width increases as it goes from the third surface 110a of the first substrate 110 toward the fourth surface 110b, or may have a constant width.

The pixel isolation pattern DTI1 may be positioned between the plurality of photoelectric converters PD to be described below. The pixel isolation pattern DTI1 may define and isolate the plurality of photoelectric converters PD to be described below. The pixel isolation pattern DTI1 may include a portion extending in the first direction (the X direction) a portion extending in the second direction (the Y direction), on a plane defined by the first direction (the X direction) and the second direction (the Y direction). The pixel isolation pattern DTI1 may have a lattice structure on a plane defined by the first direction (the X direction) and the second direction (the Y direction), and may partition the plurality of pixels PX.

The optical black area OB may include at least one black pixel OPX. In the optical black area OB, the pixel isolation pattern DTI1 may be positioned inside the first substrate 110 and isolate and define the black pixels OPX. For example, the optical black area OB may include a first black pixel OPX1 and a second black pixel OPX2, and the first black pixel OPX1 and the second black pixel OPX2 may be isolated and defined by the pixel isolation pattern DTI1. In the embodiment, a portion of the pixel isolation pattern DTI1 may be further positioned at the boundary between the optical black area OB and the peripheral area ER.

The pixel isolation pattern DTI1 may include a first insulating isolation pattern 41, a first conductive isolation pattern 43, and a first isolation capping pattern 45.

The first insulating isolation pattern 41 may extend so as to conform to the inner surface of an isolation trench. The first insulating isolation pattern 41 may contain a silicon-based insulating material (for example, silicon nitride, silicon oxide, or silicon oxynitride) or a high-dielectric constant material (for example, hafnium oxide or aluminum oxide). As another example, the first insulating isolation pattern 41 may include a plurality of layers, and the individual layers may contain different materials. In the embodiment, the first insulating isolation pattern 41 may have a refractive index lower than that of the first substrate 110. However, the material that the first insulating isolation pattern 41 contains is not limited thereto, and may be variously changed.

The first conductive isolation pattern 43 may be positioned on the first insulating isolation pattern 41. The first conductive isolation pattern 43 may be surrounded by the first insulating isolation pattern 41. The first insulating isolation pattern 41 may be positioned between the first conductive isolation pattern 43 and the first substrate 110.

The first conductive isolation pattern 43 may contain, for example, a crystalline semiconductor material such as polycrystalline silicon. The first conductive isolation pattern 43 may further contain an impurity, which may contain an impurity of the first conductivity type or an impurity of a second conductivity type. Here, the impurity of the first conductivity type may refer to a p-type impurity, and the impurity of the second conductivity type may refer to an n-type impurity.

As another example, the first conductive isolation pattern 43 may contain a crystalline semiconductor material such as undoped polycrystalline silicon. Here, the term “undoped” may mean that no intentional doping process has been performed. However, the material that the first conductive isolation pattern 43 contains is not limited thereto, and may be variously changed.

The first isolation capping pattern 45 of the pixel isolation pattern DTI1 may be positioned on the first conductive isolation pattern 43. The first conductive isolation pattern 43 and the first isolation capping pattern 45 may be positioned so as to overlap in the vertical direction (the Z direction), and the first isolation capping pattern 45 may be positioned adjacent to the third surface 110a of the first substrate 110.

In FIG. 3, it is shown that one surface of the first isolation capping pattern 45 and the third surface 110a of the first substrate 110 are flat; however, one surface of the first isolation capping pattern 45 and the third surface 110a of the first substrate 110 may have curvatures.

The first isolation capping pattern 45 may contain a non-conductive material. The first isolation capping pattern 45 may contain a silicon-based insulating material (for example, silicon nitride, silicon oxide, or silicon oxynitride) or a high-dielectric constant material (for example, hafnium oxide or aluminum oxide). However, the material that the first isolation capping pattern 45 contains is not limited thereto, and may be variously changed.

The image sensor according to the embodiment may further include an element isolation pattern STI which is positioned inside the first substrate 110.

The element isolation pattern STI may be positioned inside the first substrate 110. The element isolation pattern STI may be positioned adjacent to the third surface 110a of the first substrate 110. The element isolation pattern STI may be a shallow trench isolation (STI) layer.

The element isolation pattern STI may be penetrated by the pixel isolation pattern DTI1. In other words, the element isolation pattern STI may be positioned so as to surround a portion of the side surface of the pixel isolation pattern DTI1. Further, the element isolation pattern STI may be penetrated by the dummy isolation pattern DTI2 to be described below. The element isolation pattern STI may be positioned so as to surround a portion of the side surface of the dummy isolation pattern DTI2.

The element isolation pattern STI may have a shape whose width decreases as it goes from the third surface 110a of the first substrate 110 toward the fourth surface 110b. The element isolation pattern STI may be positioned apart from the photoelectric converters PD.

In FIG. 3, it is shown that one surface of the element isolation pattern STI and the third surface 110a of the first substrate 110 are flat; however, one surface of the element isolation pattern STI and the third surface 110a of the first substrate 110 may have curvatures.

A photoelectric converter PD in the pixel area APS may be positioned inside the first substrate 110 so as to correspond to each of a plurality of pixels PX. For example, the pixel area APS may include the plurality of pixels PX arranged two-dimensionally along the first direction (the X direction) and the second direction (the Y direction). The plurality of pixels PX may include (N×M)-number of pixels PX in an N×M array. A photoelectric converter PD may be positioned inside the first substrate 110 so as to correspond to each of the plurality of pixels PX which is arranged two-dimensionally along the first direction (the X direction) and the second direction (the Y direction). Here, each of N and M may be an integer greater than 1 independently. In the embodiment, the photoelectric converter PD may be defined by the pixel isolation pattern DTI1. Further, a photoelectric converter PD in the optical black area OB may be positioned inside the first substrate 110 so as to correspond to some of a plurality of black pixels OPX1 and OPX2.

In the embodiment, the optical black area OB may be an area where light does not enter the first substrate 110. A photoelectric converter PD in the optical black area OB may be positioned inside the first substrate 110 so as to correspond to the first black pixel OPX1 and may not be positioned inside the first substrate 110 corresponding to the second black pixel OPX2. In other words, in the optical black area OB, an area of the first substrate 110 corresponding to the second black pixel OPX2 may be a dummy area undoped with an impurity.

The photoelectric converter PD in the optical black area OB that are positioned inside the first substrate 110 so as to correspond to the first black pixel OPX1 may have a structure similar or identical to that of the photoelectric converter PD in the pixel area APS positioned inside the first substrate 110 so as to correspond to an pixel PX, but may not perform the same operation (i.e., an operation of receiving light and generating electrical signals) as that of the photoelectric converter PD positioned so as to correspond to the pixel PX.

The first black pixel OPX1 may sense the amount of charge, which may be generated from the photoelectric converter PD shielded from light, and provide a first reference charge amount. The first reference charge amount may become a relative reference value when the amounts of charge generated from the pixels PX are calculated.

Further, in the optical black area OB, a signal generated in the dummy area of the first substrate 110 corresponding to the second black pixel OPX2 may be used as information for removing process noise thereafter. In other words, the second black pixel OPX2 may sense the amount of charge, which may be generated in the state where there are no photoelectric converters PD, and provide a second reference charge amount. The second reference charge amount may be used as information for removing process noise.

The photoelectric converters PD may contain an impurity of the second conductivity type. The photoelectric converters PD may be regions in the first substrate 110, doped with an impurity of the second conductivity type. The impurity of the second conductivity type may have the opposite conductivity type to the impurity of the first conductivity type. For example, the impurity of the second conductivity type may include an n-type impurity such as phosphorus, arsenic, bismuth, and/or antimony. The n-type impurity implanted in a photoelectric converter PD may form a p-n junction with the p-type impurity implanted in the first substrate 110 to provide a photodiode.

The individual photoelectric converters PD may include first regions adjacent to the third surface 110a of the first substrate 110, and second regions adjacent to the fourth surface 110b. There may be a difference in impurity concentration between the first regions and second regions of the photoelectric converters PD. Accordingly, the photoelectric converters PD may have a potential gradient between the third surface 110a and fourth surface 110b of the first substrate 110. However, in some embodiments, the photoelectric converters PD may have no potential gradient between the third surface 110a and fourth surface 110b of the first substrate 110.

In the pixel area APS and the optical black area OB, a transfer gate TG may be positioned on the third surface 110a of the first substrate 110 so as to correspond to the pixel PX and the black pixels OPX1 and OPX2. The transfer gate TG may be positioned between the pixel isolation pattern DTI1 defining the pixel PX and the black pixels OPX1 and OPX2.

In the embodiment, the transfer gate TG may be a vertical type. A portion of the transfer gate TG may be positioned inside the first substrate 110, and the other portion may protrude from the third surface 110a of the first substrate 110. The portion of the transfer gate TG which is positioned inside the first substrate 110 may have a shape whose width decreases as it goes from the third surface 110a of the first substrate 110 toward the fourth surface 110b. Accordingly, the portion of the transfer gate TG which is positioned inside the first substrate 110 may have an inclined side surface. However, the shape of the transfer gate TG is not limited thereto, and may be variously changed. For example, the transfer gate TG may be a planar type in which the portion which is positioned inside the first substrate 110 is omitted.

Although not shown in FIG. 3, on opposite side surfaces of a first portion of the transfer gate TG, gate spacers may be further positioned. The gate spacers may contain, for example, silicon nitride, silicon carbonitride, or silicon oxynitride.

Between the transfer gate TG and the first substrate 110, a gate dielectric layer Gox may be positioned. The gate dielectric layer Gox may contain various insulating materials. For example, the gate dielectric layer Gox may contain silicon nitride, silicon carbonitride, or silicon oxynitride.

The image sensor 10 according to the embodiment may further include a floating diffusion zone FD which is positioned inside the first substrate 110.

The floating diffusion zone FD may be positioned on one side of the transfer gate TG inside the first substrate 110. The floating diffusion zone FD may be positioned adjacent to the third surface 110a of the first substrate 110. The floating diffusion zone FD may be doped with an impurity of the second conductivity type. For example, the impurity of the second conductivity type may be an n-type impurity.

The image sensor 10 according to the embodiment may be a back-illuminated image sensor. Light may enter the first substrate 110 through the fourth surface 110b of the first substrate 110. By the incident light, electron-hole pairs may be generated at the p-n junctions. The generated electrons may migrate to the photoelectric converters PD. In other words, when a voltage is applied to the transfer gate TG, the above-mentioned electrons may migrate to the floating diffusion zone FD.

The wiring layer 120 may be positioned on the third surface 110a of the first substrate 110. The wiring layer 120 may be positioned in the pixel area APS, the optical black area OB, and the peripheral area ER. The wiring layer 120 may be positioned between the second chip CH2 and the first substrate 110. For example, the wiring layer 120 may be positioned between a second surface of the second chip CH2 and the third surface 110a of the first substrate 110. The wiring layer 120 may be in contact with each of the second surface of the second chip CH2 and the third surface 110a of the first substrate 110. In the embodiment, the wiring layer 120 may be electrically connected to constituent elements which are positioned inside the first substrate 110. As an example, the wiring layer 120 may electrically connect the second chip CH2 and the first substrate 110.

The wiring layer 120 may include first to fourth connection wiring lines M1 to M4, vias VA, and first to sixth upper interlayer insulating layers IL1, IL2, IL3, IL4, IL5, and IL6 which are positioned between the third surface 110a of the first substrate 110 and the second chip CH2.

Each of the first to sixth upper interlayer insulating layers IL1, IL2, IL3, IL4, IL5, and IL6 may consist of at least one of, for example, silicon oxide films, silicon nitride films, silicon oxynitride films, and porous low dielectric films. However, the number and materials of layers that are included in the upper interlayer insulating layer IL are not limited thereto, and may be variously changed.

The first to fourth connection wiring lines M1 to M4 may be positioned between or inside the first to sixth upper interlayer insulating layers IL1, IL2, IL3, IL4, IL5, and IL6. The first to fourth connection wiring lines M1 to M4 may contain, for example, a conductive material such as copper (Cu). The first to fourth connection wiring lines M1 to M4 may be connected to one another by the vias VA which are positioned inside the first to sixth upper interlayer insulating layers IL1, IL2, IL3, IL4, IL5, and IL6.

In the embodiment, the first to fourth connection wiring lines M1 to M4 and the vias VA between them may constitute connection wiring structures CS. The connection wiring structures CS may be positioned in the pixel area APS, the power region PR, the cap region MR, the drive region DR, and the guard region GR, respectively. For example, in the pixel area APS, the first to fourth connection wiring lines M1 to M4 and the vias VA between them may constitute a second connection wiring structure CS2.

The second connection wiring structure CS2 may be positioned in the pixel area APS. The second connection wiring structure CS2 may overlap the photoelectric converter PD in the vertical direction (the Z direction). Here, the second connection wiring structure CS2 may refer to a connection wiring structure which is positioned in the pixel area APS.

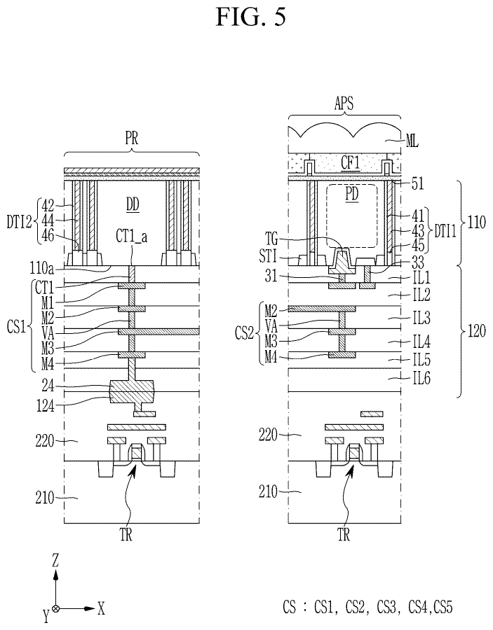

In the embodiment, the second connection wiring structure CS2 may be electrically connected to the plurality of pixels PX. The second connection wiring structure CS2 may be electrically connected to devices for controlling the plurality of pixels PX. The second connection wiring structure CS2 may be electrically connected to the photoelectric converter PD. For example, as shown in FIG. 3, the second connection wiring structure CS2 may be electrically connected to the transfer gate TG. In this case, the second connection wiring structure CS2 may transfer an electrical signal for driving the transfer transistor from a transistor TR of the second chip CH2 to the transfer gate TG. As another example, the second connection wiring structure CS2 may be electrically connected to the floating diffusion zone FD. As a further example, as shown in FIG. 5, the second connection wiring structure CS2 may be floated in the pixel area APS. In other words, the second connection wiring structure CS2 may be floated so as not to be electrically connected to the plurality of pixels PX.

In the embodiment, the second connection wiring structure CS2 may be electrically connected to at least one of the connection wiring structures which are positioned in the pixel area APS, the power region PR, the cap region MR, the drive region DR, and the guard region GR. Accordingly, a signal or a voltage applied from the second chip CH2 may be transferred to a photoelectric converter PD through the connection wiring structure and the second connection wiring structure CS2 positioned in the pixel area APS, the power region PR, the cap region MR, the drive region DR, and the guard region GR.

In the embodiment, the second connection wiring structure CS2 may include the plurality of connection wiring lines M1 to M4, but is not limited thereto and may consist of only one connection wiring line.

Also, in the image sensor according to the embodiment, in the power region PR, the first to fourth connection wiring lines M1 to M4 and the vias VA between them may constitute a first connection wiring structure CS1, and in the cap region MR, the first to fourth connection wiring lines M1 to M4 and the vias VA between them may constitute a third connection wiring structure CS3, and in the drive region DR, the first to fourth connection wiring lines M1 to M4 and the vias VA between them may constitute a fourth connection wiring structure CS4, and in the guard region GR, the first to fourth connection wiring lines M1 to M4 and the vias VA between them may constitute fifth connection wiring structure CS5. This will be described below.

The first chip CH1 of the image sensor according to the embodiment may further include a first upper contact plug 31 and a second upper contact plug 33 which are positioned inside the first upper interlayer insulating layer IL1.

The first upper contact plug 31 may pass through the first upper interlayer insulating layer IL1 in the pixel area APS and connect a transfer gate TG positioned on the third surface 110a of the first substrate 110 and the second connection wiring structure CS2.

The second upper contact plug 33 may pass through the first upper interlayer insulating layer IL1 in the pixel area APS and connect a floating diffusion zone FD positioned adjacent to the third surface 110a of the first substrate 110 and the connection wiring lines M1 to M4. In the embodiment, the second upper contact plug 33 may connect the floating diffusion zone FD and the second connection wiring structure CS2.

The first upper contact plug 31 and the second upper contact plug 33, may contain a conductive material such as tungsten, titanium nitride, tantalum nitride, and tungsten nitride, but is not limited thereto.

The first connection pad 24 may be positioned inside the sixth upper interlayer insulating layer IL6. The first connection pad 24 may be exposed from the first surface of the first chip CH1 facing the second chip CH2, and be in contact with the second connection pad 124 of the second chip CH2. The lower surface of the first connection pad 24 may be positioned together with the first surface of the first chip CH1 on the same plane. The first connection pad 24 may form a metal junction with the second connection pad 124. Accordingly, an electrical connection path between the transistor TR of the second chip CH2 and the connection wiring structures CS of the first chip CH1 may be provided. This will be described below when the second chip CH2 is described.

The image sensor 10 according to the embodiment may further include a backside insulating layer 51, a diffusion prevention pattern 53, a first optical black pattern 55, a passivation layer 57, a grid pattern 60, color filters CF1 and CF2, a second optical black pattern CFB, and the micro lens layer MLL which are positioned on the fourth surface 110b of the first substrate 110.

The backside insulating layer 51 may include at least one of a bottom antireflective coating (BARC) layer, a fixed charge layer, an adhesive layer, an antireflective layer, and a protective layer.

The fixed charge layer may consist of a metal oxide film or a metal fluoride film containing oxygen or fluorine whose amount is less than its stoichiometric ratio. Accordingly, the fixed charge layer may have negative fixed charge.

The fixed charge layer may contain metal oxide or metal fluoride containing at least one metal of hafnium (Hf), zirconium (Zr), aluminum (Al), tantalum (Ta), titanium (Ti), yttrium, and lanthanides.

Around the fixed charge layer, hole accumulation may occur. Therefore, it is possible to effectively reduce occurrence of dark current and white spots.

The antireflective layer may limit and/or prevent reflection of light such that incident light on the fourth surface 110b of the first substrate 110 can smoothly reach a photoelectric converter PD. For example, the antireflective layer may contain metal oxide (e.g., aluminum oxide or hafnium oxide) or silicon-based insulating material (e.g., silicon oxide or silicon nitride).

In the optical black area OB and the peripheral area ER, on the backside insulating layer 51, the diffusion prevention pattern 53 and the first optical black pattern 55 may be sequentially positioned.

The diffusion prevention pattern 53 may contain a metal nitride such as TiN, TaN, or WN, and the first optical black pattern 55 may contain a conductive material such as tungsten (W).

In the pixel area APS, on the backside insulating layer 51, the color filters CF1 and CF2 and the grid pattern 60 may be positioned.

The color filter CF positioned in the pixel area APS may include primary color filters. The color filter CF may include a first color filter CF1, a second color filter CF2, and a third color filter having colors different from one another. For example, the first color filter CF1 may be a green color filter, the second color filter CF2 may be a red color filter, and the third color filter may be a blue color filter. As another example, the first color filter CF1 may be a cyan color filter, the second color filter CF2 may be a magenta color filter, and the third color filter may be a yellow color filter.

In the embodiment, the color filters CF that are positioned in the pixel area APS may have a Bayer pattern on a plane. In other words, the color filters CF may have a pattern in which the number of first color filters CF1 is about twice the number of second color filters CF2 or the number of third color filters.

The first color filters CF1, the second color filter CF2, and the third color filter may be positioned so as to correspond to the plurality of pixels PX, respectively. In other words, the first color filters CF1, the second color filter CF2, and the third color filter may overlap the photoelectric converters PD, positioned so as to correspond to the plurality of pixels PX, respectively, in the vertical direction (the Z direction). In other words, the first color filters CF1, the second color filter CF2, and the third color filter may be positioned on the photoelectric converters PD, respectively.

The grid pattern 60 may be positioned between the color filters CF1 and CF2 adjacent to each other, and isolate the color filters CF1 and CF2 adjacent to each other.

The grid pattern 60 may be positioned so as to overlap a portion of the pixel isolation pattern DTI1 in the third direction Z which is the vertical direction. In other words, the grid pattern 60 and the color filters CF1 and CF2 may be shifted from the center portions of the photoelectric converters PD. In other words, the center portion of the grid pattern 60 and the center portions of the color filters CF1 and CF2 may be shifted in the first direction (the X direction) from the center portion of each photoelectric converter PD. However, the arrangement relationship between the grid pattern 60 and the pixel isolation pattern DTI1 is not limited thereto, and may be variously changed. For example, the grid pattern 60 may be positioned so as to completely overlap the pixel isolation pattern DTI1 in the vertical direction. As another example, the grid pattern 60 may be shifted so as not to overlap the pixel isolation pattern DTI1.

The degrees to which the grid pattern 60 and the color filters CF1 and CF2 are shifted from the center portions of the photoelectric converters PD may increase as the distance from the center portion of the first substrate 110 increases, i.e., as it goes toward the peripheral portion of the first substrate 110. This is for correcting light obliquely entering areas other than the center portion of the first substrate 110 such that the oblique incident light can be centered on the center of each pixel PX.

The upper surface of the grid pattern 60 may be covered by the color filters CF1 and CF2 adjacent to each other. For example, a portion of the upper surface of the grid pattern 60 may be covered by the first color filter CF1 and the other portion may be covered by the second color filter CF2. However, the arrangement relationship between the grid pattern 60 and the color filter CF is not limited thereto, and may be variously changed.

The grid pattern 60 may include a first grid pattern 62 and a second grid pattern 64 sequentially stacked. The thickness of the first grid pattern 62 in the third direction Z may be different from the thickness of the second grid pattern 64 in the third direction Z.

In the embodiment, the first grid pattern 62 and the second grid pattern 64 may contain different materials. The first grid pattern 62 may contain at least one of metal materials or metal nitrides. For example, the first grid pattern 62 may contain at least one of titanium (Ti), titanium nitride (TiN), tungsten (W), aluminum (Al), and copper (Cu).

The second grid pattern 64 may contain a material having a refractive index lower than that of the color filter CF. For example, the second grid pattern 64 may contain an organic material, such as a polymer layer containing silica nanoparticles. However, the materials which the first grid pattern 62 and the second grid pattern 64 contain are not limited thereto, and may be variously changed.

In FIG. 3, it is shown that the grid pattern 60 consists of two layers; however, the number of layers which are included in the grid pattern 60 is not limited thereto, and may be variously changed. For example, the grid pattern 60 may consist of a single layer.

In the optical black area OB and the peripheral area ER, the second optical black pattern CFB may be positioned on the backside insulating layer 51. The second optical black pattern CFB may contain, for example, the same material as that of the blue color filter.

The passivation layer 57 may be positioned between the color filters CF1 and CF2 and the backside insulating layer 51, between the grid pattern 60 and the color filters CF1 and CF2, and between the second optical black pattern CFB and the first optical black pattern 55.

The passivation layer 57 may contain an insulating material such as a high-dielectric constant material. For example, the passivation layer 57 may contain aluminum oxide or hafnium oxide.

The pixel area APS and the optical black area OB may be covered by the micro lens layer MLL. The micro lens layer MLL may not be positioned in the peripheral area ER; however, the present disclosure is not limited thereto, and the micro lens layer MLL may extend to the peripheral area ER.

The micro lens layer MLL may include a plurality of micro lenses ML which is positioned on the color filter CF in the pixel area APS. The upper surface of a micro lens ML may include a convex curved surface for refracting and condensing incident light from the outside. However, the shape of the micro lens ML is not limited thereto, and may be variously changed. For example, the upper surface of the micro lens ML may have a rectangular shape with rounded corners.

In the pixel area APS, the center portion of the micro lens ML may be shifted in the first direction (the X direction) so as to be misaligned with each of the center portion of the first color filter CF1 and the center portion of the second color filter CF2. In other words, the thickest portion of the micro lens ML may be positioned so as to be misaligned with each of the center portion of the first color filter CF1 and the center portion of the second color filter CF2.

Also, the micro lens ML may be relatively further shifted in the first direction (the X direction) from the center portion of the photoelectric converter PD as compared to the grid pattern 60 and the color filters CF1 and CF2. Accordingly, the photoelectric converters PD, the color filters CF1 and CF2, and the micro lens ML may be positioned such that they overlap but their center portions are misaligned.

Here, “overlapping” may mean not only an overlap relationship in the third direction Z which is the vertical direction but also an overlapping relationship in the propagation direction of incident light from the photoelectric converters PD. In other words, the photoelectric converter PD, the color filters CF1 and CF2, and the micro lens ML may be positioned so as to overlap along the direction of the path of incident light from the outside to the photoelectric converter PD. For example, as the center portion of the photoelectric converter PD, the center portion of the color filters CF1 and CF2, and the center portion of the micro lens ML are positioned so as to be misaligned with one another, the center portion of the photoelectric converter PD, the center portion of the color filters CF1 and CF2, and the center portion of the micro lens ML may be positioned the extension line of the path of light entering the photoelectric converter PD. This is for correcting light obliquely entering areas other than the center portion of the first substrate 110 such that the oblique incident light can be centered on the center of each pixel PX as described above.

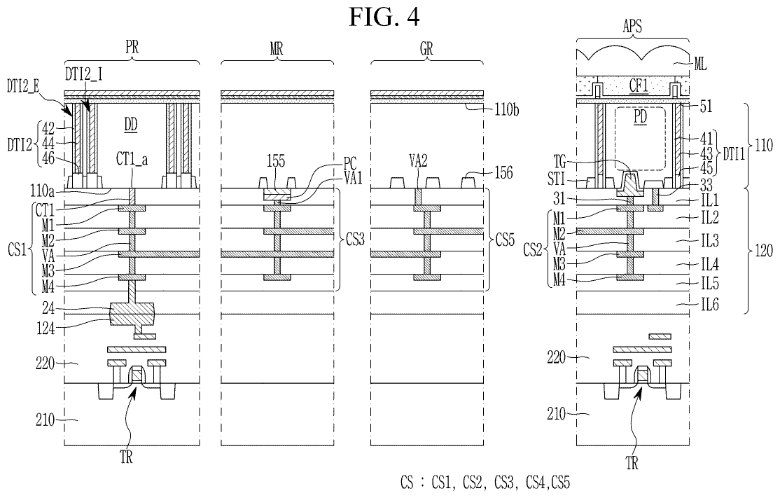

Hereinafter, the peripheral area of the image sensor according to the embodiment will be described with reference to FIGS. 4 to 6 together.

FIGS. 4 to 6 are cross-sectional views illustrating the pixel area and peripheral area of the image sensor according to the embodiment.

The peripheral area ER of the image sensor 10 according to the embodiment may include the power region PR, the cap region MR, the guard region GR, the drive region DR, and the sampler region CR.

The power region PR may include the ground portion DD which is positioned inside the first substrate 110, the dummy isolation pattern DTI2 which surrounds the ground portion DD, and the first connection wiring structure CS1 which is electrically connected to the ground portion DD.

Referring to FIGS. 4 to 6 together, the dummy isolation pattern DTI2 may be positioned inside the power region PR of the first substrate 110. The dummy isolation pattern DTI2 may pass through the first substrate 110. The dummy isolation pattern DTI2 may be frontside deep trench isolation (FDTI).

In the embodiment, the dummy isolation pattern DTI2 may completely pass through the first substrate 110. For example, the side surface of the dummy isolation pattern DTI2 may be in contact with each of the third surface 110a and fourth surface 110b of the first substrate 110. Each upper surface of the dummy isolation pattern DTI2 and the fourth surface 110b of the first substrate 110 may be flat. However, the present disclosure is not limited thereto, and each upper surface of the dummy isolation pattern DTI2 may include a surface curved with respect to the fourth surface 110b of the first substrate 110.

In the embodiment, the dummy isolation pattern DTI2 may have a shape whose width decreases as it goes from the third surface 110a of the first substrate 110 toward the fourth surface 110b. In other words, the dummy isolation pattern DTI2 may have an inclined side surface. However, the present disclosure is not limited thereto, and the dummy isolation pattern DTI2 may have a shape whose width increases as it goes from the third surface 110a of the first substrate 110 toward the fourth surface 110b, or may have a constant width.

The dummy isolation pattern DTI2 may be positioned in the peripheral area ER. For example, as shown in FIG. 4, the dummy isolation pattern DTI2 may be positioned in the power region PR. The dummy isolation pattern DTI2 may surround the ground portion DD of the first substrate 110 positioned in the power region PR to be described below. The dummy isolation pattern DTI2 may define the ground portion DD to be described below. In other words, a portion of the first substrate 110 surrounded by the dummy isolation pattern DTI2 may be defined as the ground portion DD. Accordingly, the ground portion DD may be isolated from the other portion of the first substrate 110 by the dummy isolation pattern DTI2. The dummy isolation pattern DTI2 may be frontside deep trench isolation (FDTI), but is not limited thereto. For example, the dummy isolation pattern DTI2 may be backside deep trench isolation (BDTI).

In an embodiment, a plurality of dummy isolation patterns DTI2 may be provided. For example, a dummy isolation pattern DTI2 may include an internal dummy isolation pattern DTI2_I which surrounds the ground portion DD, and an external dummy isolation pattern DTI2_E which surrounds the internal dummy isolation pattern DTI2_I. Accordingly, the ground portion DD and the photoelectric converter PD can be effectively insulated from each other.

In the embodiment, the upper surface of the dummy isolation pattern DTI2 may be positioned substantially at the same level as the upper surface of the pixel isolation pattern DTI1. In other words, the upper surface of the dummy isolation pattern DTI2 and the upper surface of the pixel isolation pattern DTI1 may be positioned substantially at the same distance from the fourth surface 110b of the first substrate 110. Accordingly, the length of the dummy isolation pattern DTI2 in the third direction (the Z direction) may be the same or substantially the same as the length of the pixel isolation pattern DTI1 in the third direction (the Z direction); however, the present disclosure is not limited thereto.

In the embodiment, the dummy isolation pattern DTI2 may be positioned apart from the pixel isolation pattern DTI1. Since the power region PR is spaced apart from the pixel area APS and the optical black area OB as described above, the dummy isolation pattern DTI2 which surrounds the ground portion DD in the power region PR may be positioned apart from the pixel isolation pattern DTI1 which is positioned between the photoelectric converters PD.

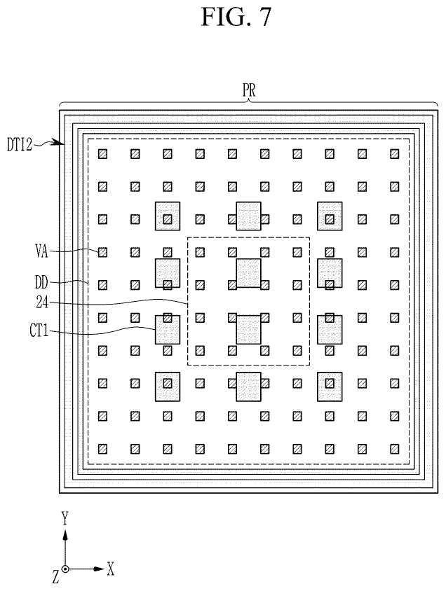

Although it is shown in FIG. 4 that the dummy isolation pattern DTI2 is positioned in the power region PR, the present disclosure is not limited thereto, and the dummy isolation pattern DTI2 may be further positioned in the drive region DR. This will be described below with reference to FIG. 7.

The dummy isolation pattern DTI2 may include a second insulating isolation pattern 42, a second conductive isolation pattern 44, and a second isolation capping pattern 46.

The second insulating isolation pattern 42 may extend so as to conform to the inner surface of an isolation trench. The second insulating isolation pattern 42 may contain the same material as that of the first insulating isolation pattern 41. The second insulating isolation pattern 42 may contain a silicon-based insulating material (for example, silicon nitride, silicon oxide, or silicon oxynitride) or a high-dielectric constant material (for example, hafnium oxide or aluminum oxide). As another example, the second insulating isolation pattern 42 may include a plurality of layers, and the individual layers may contain different materials. In the embodiment, the second insulating isolation pattern 42 may have a refractive index lower than that of the first substrate 110. However, the material that the second insulating isolation pattern 42 contains is not limited thereto, and may be variously changed.

The second conductive isolation pattern 44 may be positioned on the second insulating isolation pattern 42. The second conductive isolation pattern 44 may be surrounded by the second insulating isolation pattern 42. The second insulating isolation pattern 42 may be positioned between the second conductive isolation pattern 44 and the first substrate 110.

The second conductive isolation pattern 44 may contain the same material as that of the first conductive isolation pattern 43. For example, the second conductive isolation pattern may contain a crystalline semiconductor material such as polycrystalline silicon. The second conductive isolation pattern 44 may further contain an impurity, which may contain an impurity of the first conductivity type or an impurity of a second conductivity type. Here, the impurity of the first conductivity type may refer to a p-type impurity, and the impurity of the second conductivity type may refer to an n-type impurity.

As another example, the second conductive isolation pattern 44 may contain a crystalline semiconductor material such as undoped polycrystalline silicon. Here, the term “undoped” may mean that no intentional doping process has been performed. However, the material that the second conductive isolation pattern 44 contains is not limited thereto, and may be variously changed.

The second isolation capping pattern 46 of the dummy isolation pattern DTI2 may be positioned on the second conductive isolation pattern 44. The second conductive isolation pattern 44 and the second isolation capping pattern 46 may be positioned so as to overlap in the vertical direction (the Z direction), and the second isolation capping pattern 46 may be positioned adjacent to the third surface 110a of the first substrate 110.

In FIG. 4, it is shown that one surface of the second isolation capping pattern 46 and the third surface 110a of the first substrate 110 are flat; however, one surface of the second isolation capping pattern 46 and the third surface 110a of the first substrate 110 may have curvatures.

The second isolation capping pattern 46 may contain the same material as that of the first isolation capping pattern 45. The second isolation capping pattern 46 may contain a non-conductive material. The second isolation capping pattern 46 may contain a silicon-based insulating material (for example, silicon nitride, silicon oxide, or silicon oxynitride) or a high-dielectric constant material (for example, hafnium oxide or aluminum oxide). However, the material that the second isolation capping pattern 46 contains is not limited thereto, and may be variously changed.

The ground portion DD may be positioned inside the first substrate 110 in the peripheral area ER. For example, the ground portion DD may be positioned inside the first substrate 110 in the power region PR. The ground portion DD may be defined by the dummy isolation pattern DTI2. The ground portion DD may be surrounded by the dummy isolation pattern DTI2. The ground portion DD may be completely surrounded by the dummy isolation pattern DTI2. Accordingly, the ground portion DD may be spaced apart from the photoelectric converters PD. The ground portion DD may be electrically insulated from the photoelectric converters PD by the dummy isolation pattern DTI2. The ground portion DD may overlap the dummy isolation pattern DTI2 in the first direction (the X direction). In the embodiment, the ground portion DD may be positioned together with the photoelectric converter PD in the same layer.

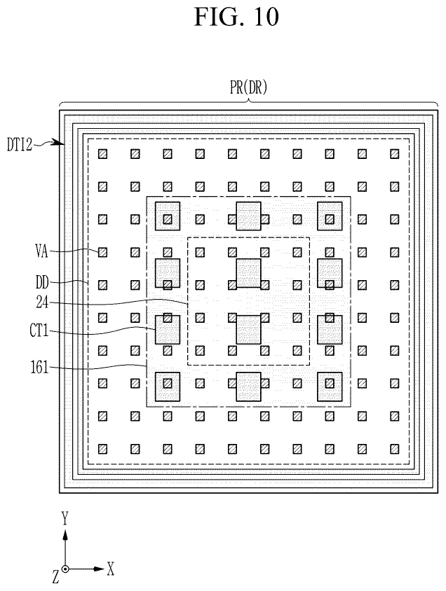

In the embodiment, the ground portion DD may contain an impurity of the first conductivity type. The ground portion DD may be doped with the impurity of the first conductivity type. For example, the impurity of the first conductivity type may be a p-type impurity such as aluminum (Al), boron (B), indium (In), and/or gallium (Ga); However, the present disclosure is not limited thereto. In some embodiments, in the ground portion DD, a region doped at a different concentration may be further included. This will be described below with reference to FIG. 10.

The ground portion DD may be electrically connected to the first connection wiring structure CS1. The ground portion DD may be electrically connected to a first contact electrode CT1 of the first connection wiring structure CS1 to be described below. One surface of the ground portion DD may be in contact with the first contact electrode CT1 to be described below. Accordingly, the ground portion DD may be electrically connected to the second chip CH2 through the first connection wiring structure CS1.

In the embodiment, the first to fourth connection wiring lines M1 to M4 of the wiring layer 120 and the vias VA between them may constitute the first connection wiring structure CS1 in the power region PR. The first connection wiring structure CS1 may electrically connect the ground portion DD and the second chip CH2. The first connection wiring structure CS1 may be described below.

In the image sensor 10 according to the embodiment, the guard region GR may include a guard pattern 156 which is positioned inside the first substrate 110.

The guard pattern 156 may be positioned inside the first substrate 110 in the guard region GR. The guard pattern 156 may be positioned adjacent to the third surface 110a of the first substrate 110. The guard pattern 156 may be a shallow trench isolation (STI) layer. The guard pattern 156 may function to block light or electrons, which may be generated by a specific circuit in the peripheral area ER, from penetrating into the pixel area APS and/or the optical black area OB.

The width of the guard pattern 156 may have a shape whose width decreases as it goes from the third surface 110a of the first substrate 110 toward the fourth surface 110b. The guard pattern 156 may be positioned apart from the dummy isolation pattern DTI2 and the pixel isolation pattern DTI1. Further, the guard pattern 156 may be positioned apart from the ground portion DD and the photoelectric converters PD.

In FIG. 4, it is shown that one surface of the guard pattern 156 and the third surface 110a of the first substrate 110 are flat; however, one surface of the guard pattern 156 and the third surface 110a of the first substrate 110 may have curvatures.

Referring to FIG. 3 again, the second chip CH2 may include a second substrate 210, a plurality of transistors TR which is positioned inside the second substrate 210, a lower interlayer insulating layer 220 which covers the second substrate 210, and the second connection pad 124 which is positioned inside the lower interlayer insulating layer 220.

In the embodiment, the second chip CH2 may include a second surface facing the first surface of the first chip CH1. The second surface of the second chip CH2 may face the first surface of the first chip CH1. The second surface of the second chip CH2 may be the upper surface of the second chip CH2.

The lower interlayer insulating layer 220 may have a single film or multiple film structure of at least one of silicon oxide films, silicon nitride films, silicon oxynitride films, and porous insulating films.

In the embodiment, the second chip CH2 may have a chip-to-chip (C2C) structure bonded to the first chip CH1 by a wafer bonding method (for example, hybrid bonding). For example, the second surface of the second chip CH2 may be a bonding surface with the first surface of the first chip CH1. Further, the first surface of the first chip CH1 may be a bonding surface with the second surface of the second chip CH2. Specifically, the second connection pad 124 of the second chip CH2 may form a metal junction with the first connection pad 24 of the first chip CH1. The first surface of the first chip CH1 and the lower surface of the first connection pad 24 may be positioned on the same plane, and the second surface of the second chip CH2 and the upper surface of the second connection pad 124 may be positioned on the same plane. In the embodiment, the first surface of the first chip CH1 and the second surface of the second chip CH2 may be in contact with each other. Accordingly, the second connection pad 124 may be bonded to the first connection pad 24, thereby providing an electrical connection path from the transistor TR of the second chip CH2 to the connection wiring structures CS of the first chip CH1.

In the embodiment, the second connection pad 124 may contain the same conductive material as that of the first connection pad 24, for example, copper.

Although not shown in FIGS. 3 and 4, a bonding insulating layer may be further positioned at the interface between the first chip CH1 and the second chip CH2. In other words, the first chip CH1 may include an upper bonding insulating layer at the interface with the second chip CH2, and the second chip CH2 may include a lower bonding insulating layer at the interface with the first chip CH1, and the upper bonding insulating layer and the lower bonding insulating layer may be in direct contact with each other. The upper bonding insulating layer and the lower bonding insulating layer may be bonded to form a junction insulation layer. For example, the upper bonding insulating layer and the lower bonding insulating layer may contain at least one of SiCN, SiOCN, and SiC.

Hereinafter, the wiring layer of the image sensor according to the embodiment will be described with reference to FIG. 2 and FIGS. 4 to 6.

Referring to FIG. 2 and FIGS. 4 to 6, the wiring layer 120 of the image sensor 10 according to the embodiment may include the first to fourth connection wiring lines M1 to M4 and the vias VA between them. In the embodiment, the first to fourth connection wiring lines M1 to M4 and the vias VA between them may constitute connection wiring structures CS.

Specifically, the wiring layer may include the first connection wiring structure CS1 which is positioned in the power region PR, and may further include the third connection wiring structure CS3 which is positioned in the cap region MR, the fourth connection wiring structure CS4 which is positioned in the drive region DR, and the fifth connection wiring structure CS5 which is positioned in the guard region GR.

The first connection wiring structure CS1 may be positioned in the power region PR. The first connection wiring structure CS1 may overlap the ground portion DD in the vertical direction (the Z direction). The first connection wiring structure CS1 may be electrically connected to the ground portion DD. At least a portion of the first connection wiring structure CS1 may be in contact with the ground portion DD. In the embodiment, the first connection wiring structure CS1 may overlap the first connection pad 24 and the second connection pad 124 in the vertical direction (the Z direction). Here, the first connection wiring structure CS1 may refer to a connection wiring structure which is positioned inside the power region PR.

The first connection wiring structure CS1 may be electrically connected to the first connection pad 24 which is positioned inside the sixth upper interlayer insulating layer IL6. Accordingly, the first connection wiring structure CS1 may be electrically connected to the transistor TR of the second chip CH2 through the first connection pad 24 and the second connection pad 124.

In the embodiment, the first connection wiring structure CS1 may include the first to fourth connection wiring lines M1 to M4, the vias VA which connect them, and the first contact electrode CT1 which is positioned between the first to fourth connection wiring lines M1 to M4 and the ground portion DD.

The first to fourth connection wiring lines M1 to M4 may be positioned on the first connection pad 24. The vias VA may connect the first to fourth connection wiring lines M1 to M4. The first to fourth connection wiring lines M1 to M4 may contain, for example, a conductive material such as copper (Cu).

In FIGS. 4 and 5, the four connection wiring lines M1 to M4 are shown; however, the present disclosure is not limited thereto, and three or less connection wiring lines M1 to M4 may be included, or five or more connection wiring lines M1 to M4 may be included. Also, in FIGS. 4 and 5, one via is shown in each of the positions between the first connection wiring line M1 and the second connection wiring line M2, between the second connection wiring line M2 and the third connection wiring line M3, and the third connection wiring line M3 and the fourth connection wiring line M4; however, the number of vias VA is not limited thereto. This will be described below with reference to FIG. 7.

The first contact electrode CT1 may be positioned between the first to fourth connection wiring lines M1 to M4 and the ground portion DD. For example, the first contact electrode CT1 may be positioned between the first connection wiring line M1 positioned at the top and the ground portion DD. Here, the first connection wiring line M1 may be a connection wiring line closest to the third surface 110a of the first substrate 110.

The first contact electrode CT1 may pass through the first upper interlayer insulating layer LI1. The first contact electrode CT1 may be positioned together with the first upper contact plug 31 and the second upper contact plug 33 in the same layer. In the embodiment, the upper surface of the first contact electrode CT1 may be positioned substantially at the same level as the upper surface of the second upper contact plug 33; however, the present disclosure is not limited thereto. In other words, the upper surface of the first contact electrode CT1 and the upper surface of the second upper contact plug 33 may be positioned substantially at the same distance from the second surface of the second chip CH2.

The first contact electrode CT1 may be electrically connected to the ground portion DD. The first contact electrode CT1 may be in contact with the ground portion DD. The first contact electrode CT1 may electrically connect the first to fourth connection wiring lines M1 to M4 and the ground portion DD. Accordingly, the transistor TR of the second chip CH2 may have an electrical connection path with the ground portion DD through the first to fourth connection wiring lines M1 to M4 and the first contact electrode CT1.

The first contact electrode CT1 may contain a conductive material. For example, the first contact electrode CT1 may contain a conductive material such as copper (Cu). As another example, the first contact electrode CT1 may contain a conductive material such as tungsten, titanium nitride, tantalum nitride, and tungsten nitride, but is not limited thereto.

In FIGS. 4 and 5, it is shown that one first contact electrode CT1 is positioned between the first connection wiring line M1 and the ground portion DD; however, the present disclosure is not limited thereto. For example, two or more first contact electrodes CT1 may be included between the first connection wiring line M1 and the ground portion DD.

In the embodiment, the first connection wiring structure CS1 may be electrically connected to the second connection wiring structure CS2. At least one of the first to fourth connection wiring lines M1 to M4 of the first connection wiring structure CS1 may extend to the pixel area APS and be electrically connected to the second connection wiring structure CS2. For example, as shown in FIG. 4, the third connection wiring line M3 of the first connection wiring structure CS1 may extend to the cap region MR and the guard region GR and be electrically connected to the fifth connection wiring structure CS5 of the guard region GR, and the second connection wiring line M2 of the fifth connection wiring structure CS5 may extend to the pixel area APS and be electrically connected to the second connection wiring structure CS2. However, the present disclosure is not limited thereto, and any one connection wiring line of the first connection wiring structure CS1 may extend to the pixel area APS and be connected directly to the second connection wiring structure CS2.

In this case, as shown in FIG. 4, the second connection wiring structure CS2 may be electrically connected to each of the plurality of pixels PX. In this case, an electrical connection path from the second chip CH2 to the plurality of pixels PX may be formed through the first connection wiring structure CS1, the fifth connection wiring structure CS5, and the second connection wiring structure CS2. Meanwhile, as shown in FIG. 5, the second connection wiring structure CS2 may be floated.

The third connection wiring structure CS3 may be positioned in the cap region MR. The third connection wiring structure CS3 may overlap a portion of the first substrate 110 positioned in the cap region MR, in the vertical direction (the Z direction).

In the embodiment, the third connection wiring structure CS3 may include the first to fourth connection wiring lines M1 to M4, the vias VA which connect them, and a capacitor element which is positioned between the first to fourth connection wiring lines M1 to M4 and the first substrate 110.

For example, the third connection wiring structure CS3 may include a first electrode PC and a dielectric layer 155 which are sequentially positioned on the first connection wiring line M1. The first electrode PC may contain a conductive material. The dielectric layer 155 may be positioned between the first substrate 110 and the first electrode PC. In the embodiment, the portion of the first substrate 110 which is positioned in the cap region MR, the dielectric layer 155, and the first electrode PC may constitute the capacitor element. The capacitor element may function to decouple noise present in a driving signal to be provided to the plurality of pixels PX and/or pixel signals received from the plurality of pixels PX.

However, the present disclosure is not limited thereto, and the capacitor element of the third connection wiring structure CS3 may be configured as a capacitor element in which a gate insulating layer functions as a dielectric layer in a transistor structure including a source, a drain, and a gate.

In the embodiment, the third connection wiring structure CS3 may be electrically connected to the first connection wiring structure CS1. At least one of the first to fourth connection wiring lines M1 to M4 of the third connection wiring structure CS3 may extend to the power region PR and be electrically connected to the first connection wiring structure CS1. For example, as shown in FIG. 4, the third connection wiring line M3 of the third connection wiring structure CS3 may extend to the power region PR and be electrically connected to the first connection wiring structure CS1. Further, the third connection wiring line M3 of the third connection wiring structure CS3 may extend to the guard region GR and be electrically connected to the fifth connection wiring structure CS5.

The fifth connection wiring structure CS5 may be positioned in the guard region GR. The fifth connection wiring structure CS5 may overlap the portion of the first substrate 110 which is positioned in the guard region GR, in the vertical direction (the Z direction).

In the embodiment, the fifth connection wiring structure CS5 may include the first to fourth connection wiring lines M1 to M4, the vias VA which connect them, and a through-hole via VA2 which is positioned between the first to fourth connection wiring lines M1 to M4 and the first substrate 110.

The through-hole via VA2 may be positioned between the first to fourth connection wiring lines M1 to M4 and the first substrate 110 positioned in the guard region GR. For example, the through-hole via VA2 may be positioned between the first connection wiring line M1 positioned at the top and the first substrate 110. Here, the first connection wiring line M1 may be a connection wiring line closest to the third surface 110a of the first substrate 110.

The through-hole via VA2 may pass through the first upper interlayer insulating layer IL1. The through-hole via VA2 may be positioned together with the first contact electrode CT1, the first upper contact plug 31, and the second upper contact plug 33 in the same layer. In the embodiment, the upper surface of the through-hole via VA2 may be positioned substantially at the same level as the upper surface CT1_a of the first contact electrode CT1 and the upper surface of the second upper contact plug 33; however, the present disclosure is not limited thereto. In other words, the upper surface of the through-hole via VA2, the upper surface CT1_a of the first contact electrode CT1, and the upper surface of the second upper contact plug 33 may be positioned substantially at the same distance from the second surface of the second chip CH2.

The through-hole via VA2 may be electrically connected to the first substrate 110. The through-hole via VA2 may be in contact with the first substrate 110. For example, the through-hole via VA2 may be in contact with the portion of the first substrate 110 positioned between the guard pattern 156. The through-hole via VA2 may electrically connect the first to fourth connection wiring lines M1 to M4 and the first substrate 110. Accordingly, the transistor TR of the second chip CH2 may have an electrical connection path with the guard region GR through the first to fourth connection wiring lines M1 to M4 and the through-hole via VA2. Accordingly, the guard region GR may function to block light or electrons, which may be generated by a specific circuit in the peripheral area ER, from penetrating into the pixel area APS and/or the optical black area OB.

The through-hole via VA2 may contain a conductive material. The through-hole via VA2 may contain the same material as that of the first contact electrode CT1, but is not limited thereto. For example, the through-hole via VA2 may contain a conductive material such as copper (Cu). As another example, the through-hole via VA2 may contain a conductive material such as tungsten, titanium nitride, tantalum nitride, and tungsten nitride, but is not limited thereto.

In the embodiment, the fifth connection wiring structure CS5 may be electrically connected to the second connection wiring structure CS2. At least one of the first to fourth connection wiring lines M1 to M4 of the fifth connection wiring structure CS5 may extend to the pixel area APS and be electrically connected to the first connection wiring structure CS1. Further, the fifth connection wiring structure CS5 may be electrically connected to the second connection wiring structure CS2 and the third connection wiring structure CS3. At least one of the first to fourth connection wiring lines M1 to M4 of the fifth connection wiring structure CS5 may extend to the power region PR and the cap region MR and be electrically connected to the first connection wiring structure CS1 and the third connection wiring structure CS3.

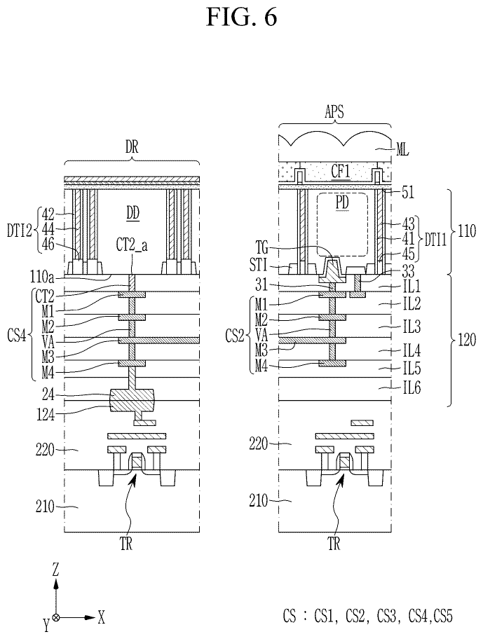

Referring to FIG. 6 together, the ground portion DD of the image sensor 10 according to the embodiment may be further positioned in the drive region DR. In the embodiment, the wiring layer 120 may include the fourth connection wiring structure CS4 which is positioned in the drive region DR.

The fourth connection wiring structure CS4 may be positioned in the drive region DR. The fourth connection wiring structure CS4 may overlap the ground portion DD in the vertical direction (the Z direction). The fourth connection wiring structure CS4 may be electrically connected to the ground portion DD. At least a portion of the fourth connection wiring structure CS4 may be in contact with the ground portion DD. Here, the fourth connection wiring structure CS4 may refer to a connection wiring structure which is positioned in the drive region DR.

In the embodiment, the fourth connection wiring structure CS4 may include the first to fourth connection wiring lines M1 to M4, the vias VA which connect them, and a second contact electrode CT2 which is positioned between the first to fourth connection wiring lines M1 to M4 and the ground portion DD.

The second contact electrode CT2 may be positioned between the first to fourth connection wiring lines M1 to M4 and the ground portion DD. For example, the second contact electrode CT2 may be positioned between the first connection wiring line M1 positioned at the top and the ground portion DD. Here, the first connection wiring line M1 may be a connection wiring line closest to the third surface 110a of the first substrate 110.

The second contact electrode CT2 may pass through the first upper interlayer insulating layer IL1. The second contact electrode CT2 may be positioned together with the first contact electrode CT1 in the same layer. The second contact electrode CT2 may be electrically connected to the ground portion DD. The second contact electrode CT2 may be in contact with the ground portion DD. In other words, the upper surface CT2_a of the second contact electrode CT2 may electrically connect the first to fourth connection wiring lines M1 to M4 and the ground portion DD. The second contact electrode CT2 may contain a conductive material. The second contact electrode CT2 may contain the same material as that of the first contact electrode CT1, but is not limited thereto. A residual description of the second contact electrode CT2 is substantially identical to the description of the first contact electrode CT1, and thus, will not be made.

In the embodiment, the fourth connection wiring structure CS4 may be electrically connected to the second connection wiring structure CS2. At least one of the first to fourth connection wiring lines M1 to M4 of the fourth connection wiring structure CS4 may extend to the pixel area APS and be electrically connected to the second connection wiring structure CS2. For example, as shown in FIG. 6, the third connection wiring line M3 of the fourth connection wiring structure CS4 may extend to the pixel area APS and be electrically connected to the second connection wiring structure CS2. In this case, the second connection wiring structure CS2 may be electrically connected to the transfer gate TG through the first upper contact plug 31. Accordingly, an electrical connection path may be formed from the transistor TR of the second chip CH2 to the transfer gate TG via the second connection pad 124, the first connection pad 24, the fourth connection wiring structure CS4, and the second connection wiring structure CS2. A driving signal which is applied from the second chip CH2 may be applied to the transfer gate TG through the fourth connection wiring structure CS4 and the second connection wiring structure CS2.

In the embodiment, the shape, arrangement, and connection relationship between the fourth connection wiring structure CS4 of the drive region DR and the ground portion DD may be substantially identical to the shape, arrangement, and connection relationship between the first connection wiring structure CS1 of the power region PR and the ground portion DD.

It has been described with reference to FIGS. 4 to 6 that each of the connection wiring structures CS includes four connection wiring lines M1 to M4 and one via VA is positioned in each of the positions between the connection wiring lines M1 to M4; however, the number of connection wiring lines M1 to M4 and the number of vias VA are not limited thereto.

Hereinafter, the power region of the image sensor according to the embodiment will be described with reference to FIG. 7 together.

FIG. 7 is a plan view illustrating the power region of the image sensor according to the embodiment, as an example. In FIG. 7, for ease of explanation, the dummy isolation pattern DTI2, the ground portion DD, the first contact electrode CT1, the vias VA, and the first connection pad 24 of the power region PR are shown, and the other components are omitted. Hereinafter, the planar arrangement relationship of the ground portion DD, the first contact electrode CT1, and the vias VA will be described with reference to FIG. 7.

Referring to FIG. 7 together, the image sensor according to the embodiment may include a plurality of vias VA. For example, the first connection wiring structure CS1 which is positioned in the power region PR may include a plurality of vias VA which is arranged in the first direction (the X direction) and the second direction (the Y direction). The plurality of vias VA may be positioned apart from each other on a plane. The plurality of vias VA may overlap the ground portion DD in the vertical direction (the Z direction).

In the embodiment, a plurality of first contact electrodes CT1. For example, the first connection wiring structure CS1 which is positioned in the power region PR may include a plurality of first contact electrodes CT1 which is arranged in the first direction (the X direction) and the second direction (the Y direction). The plurality of first contact electrodes CT1 may be positioned apart from each other on a plane. The plurality of first contact electrodes CT1 may overlap the ground portion DD in the vertical direction (the Z direction). In the embodiment, at least some of the plurality of first contact electrodes CT1 may overlap the vias VA in the vertical direction (the Z direction); however, the present disclosure is not limited thereto. In the embodiment, at least some of the plurality of first contact electrodes CT1 may overlap the first connection pad 24 in the vertical direction (the Z direction). For example, as shown in FIG. 7, the first connection pad 24 may overlap two first contact electrodes CT1 in the vertical direction (the Z direction); however, the number of first contact electrodes CT1 which overlap the first connection pad 24 in the vertical direction (the Z direction) is not limited thereto.

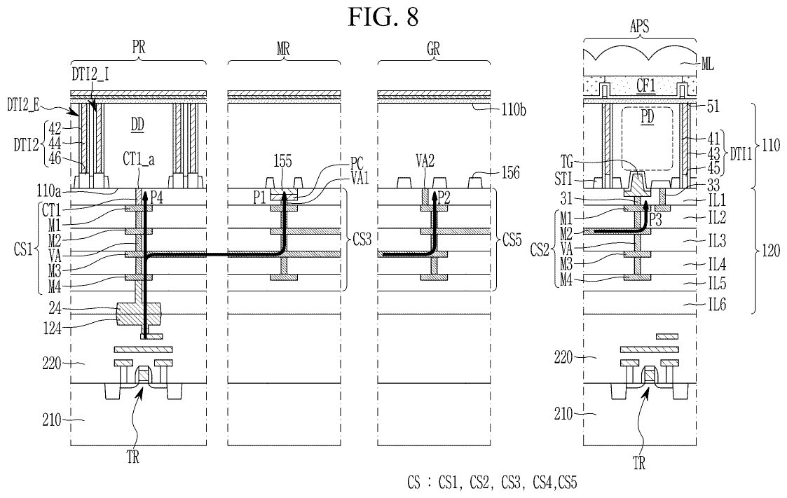

Hereinafter, an image sensor according to an embodiment will be described with reference to FIG. 8.

FIG. 8 is a cross-sectional view illustrating the pixel area and peripheral area of the image sensor according to the embodiment.

Referring to FIG. 8, as described above, a desired and/or alternatively predetermined signal and/or voltage may be applied from the transistor TR of the second chip CH2 to the first chip CH1. The transistor TR of the second chip CH2 may be electrically connected to the second connection pad 124 and the first connection pad 24, and be electrically connected to elements of the first chip CH1 through the wiring layer 120.

For example, the first connection wiring structure CS1 which is positioned in the power region PR is connected directly to the first connection wiring line M1. Accordingly, the first connection wiring structure CS1 may be electrically connected to the transistor TR of the second chip CH2.

In the embodiment, as the first connection wiring structure CS1 is electrically connected to the third connection wiring structure CS3 which is positioned in the cap region MR, it is possible to provide a first path P1 which is an electrical connection path between the second chip CH2 and the capacitor element of the cap region MR through the first connection wiring structure CS1 and the third connection wiring structure CS3.

Further, as the first connection wiring structure CS1 is electrically connected to the fifth connection wiring structure CS5 which is positioned in the guard region GR, it is possible to provide a second path P2 which is an electrical connection path between the second chip CH2 and the first substrate 110 of the guard region GR through the first connection wiring structure CS1 and the fifth connection wiring structure CS5.

Furthermore, as the first connection wiring structure CS1 is electrically connected to the second connection wiring structure CS2 which is positioned in the pixel area APS, it is possible to provide a third path P3 which is an electrical connection path between the second chip CH2 and the plurality of pixels PX of the pixel area APS through the first connection wiring structure CS1 and the second connection wiring structure CS2.

Moreover, since the first connection wiring structure CS1 is electrically connected to the ground portion DD through the first contact electrode CT1, it is possible to provide a fourth path P4 which is an electrical connection path between the second chip CH2 and the ground portion DD through the first contact electrode CT1.

In the procedure of forming the image sensor 10 according to the embodiment, a plasma process may be repeatedly performed. When a plasma process is performed, charge may be generated, and the generated charge may be accumulated in the wiring layer 120 or the like. The accumulated charge may be released into the first substrate 110 through the connection wiring structures CS of the wiring layer 120. For example, the charge accumulated through the plasma process may be released into the first substrate 110 through the first path P1 to the third path P3.

Meanwhile, in the procedure of forming the wiring layer 120 of the image sensor 10 according to the embodiment, there may be a step before the second to fifth connection wiring structures CS2 to CS5 are electrically connected to the first substrate 110. In this case, the first path P1 to the third path P3 may not be completely formed, and at this time, the charge accumulated in the wiring layer 120 by the plasma process may not be released through the first path P1 to the third path P3. Since the first contact electrode CT1 is electrically connected to the ground portion DD of the power region PR, even though the first path P1 to the third path P3 are not completely formed, the first connection wiring structure CS1 of the image sensor 10 according to the embodiment may be discharged through the fourth path P4. Accordingly, the reliability of the image sensor 10 according to the embodiment can improve.

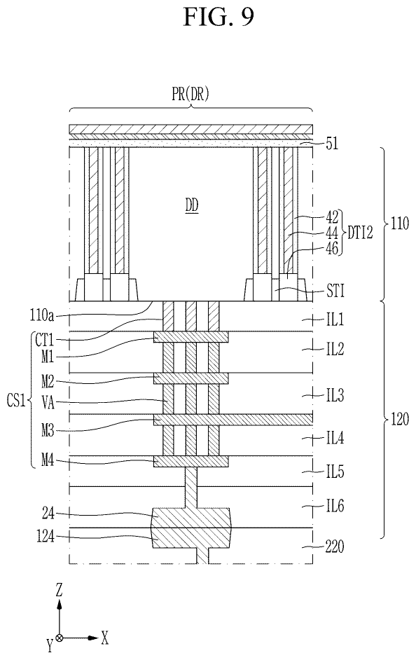

Hereinafter, image sensors according to various embodiment will be described with reference to FIGS. 9 to 19. In the following embodiments, components identical to those in the above-described embodiment will be denoted by the same reference symbols, and a redundant description thereof will not be made or will be made in brief, and the differences in them from the above-described embodiment will be mainly described.

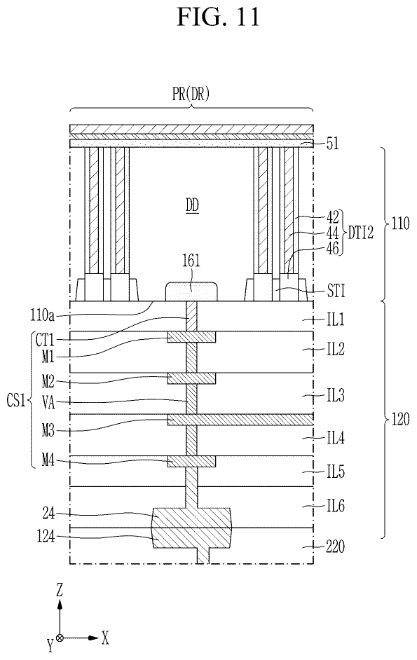

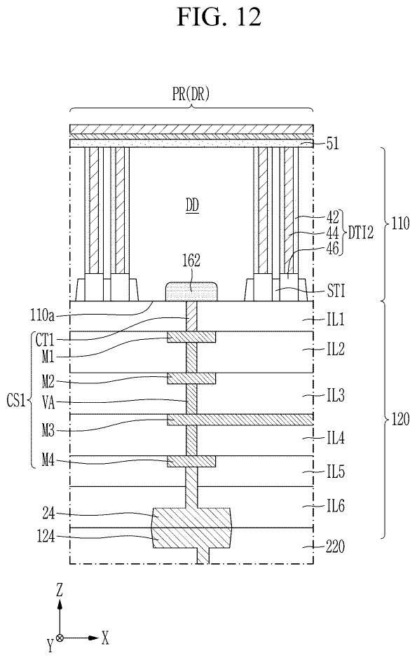

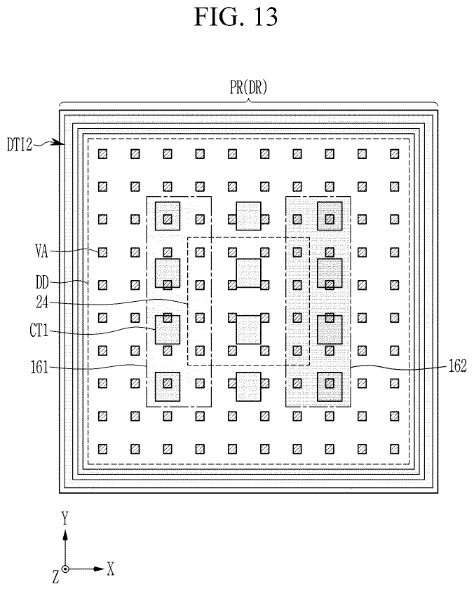

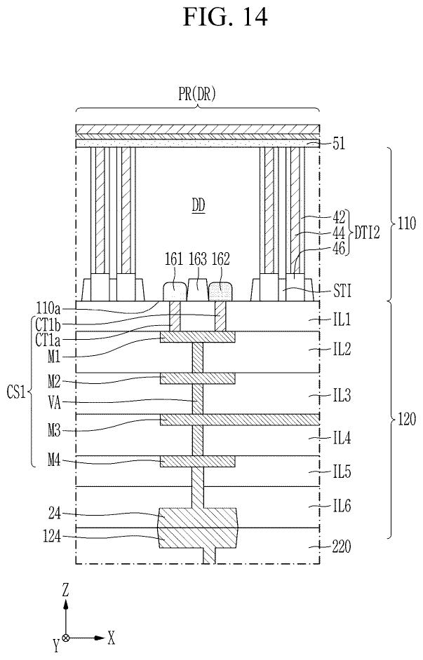

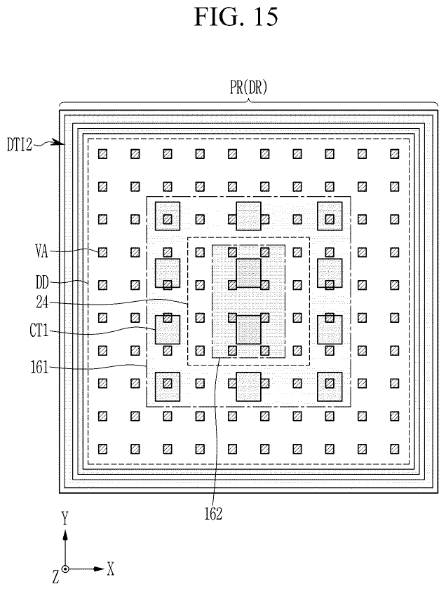

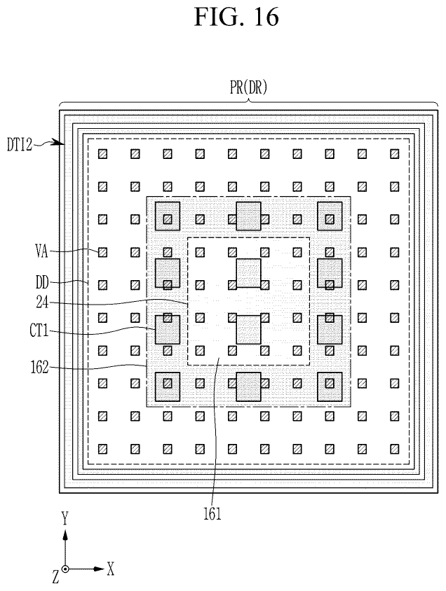

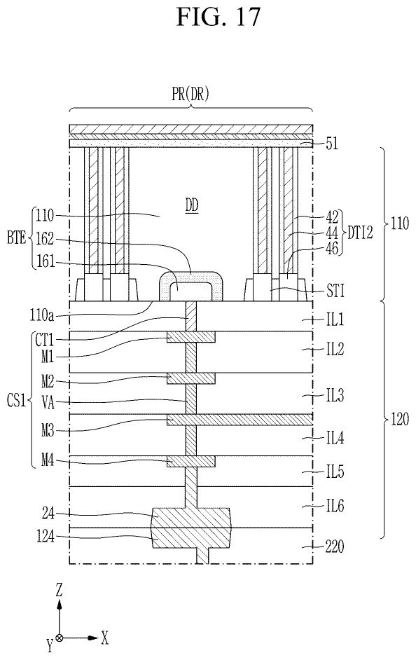

FIG. 9 is a cross-sectional view illustrating a power region of an image sensor according to some embodiments. FIG. 10 is a plan view illustrating the power region of the image sensor according to some embodiments, as an example. FIGS. 11 and 12 are cross-sectional views illustrating the power region of the embodiment of FIG. 10. FIG. 13 is a plan view illustrating the power region of the image sensor according to some embodiments, as an example. FIG. 14 is a cross-sectional view illustrating the power region of the embodiment of FIG. 13. FIG. 15 is a plan view illustrating the power region of the image sensor according to some embodiments, as an example. FIG. 16 is a plan view illustrating the power region of the image sensor according to some embodiments, as an example. FIGS. 17 to 19 are cross-sectional views illustrating the power region of the embodiment of FIG. 15.

In the embodiment of FIGS. 9 to 19, the power region PR is shown, and the pixel area APS, the optical black area OB, the guard region GR, the cap region MR, and the sampler region CR are not shown. It is apparent that a description of the power region PR of the embodiment of FIGS. 9 to 19 may be equally applied to the drive region DR.

Referring to FIG. 9, the first connection wiring structure CS1 of the image sensor 10 according to some embodiments may include a plurality of first contact electrodes CT1. The plurality of first contact electrodes CT1 may be positioned on the first connection wiring line M1. The plurality of first contact electrodes CT1 may be positioned apart from each other in the first direction (the X direction) and the second direction (the Y direction). The plurality of first contact electrodes CT1 may be arranged in the first direction (the X direction) and the second direction (the Y direction). Even in this case, each of the plurality of first contact electrodes CT1 may be in contact with one surface of the ground portion DD. The plurality of first contact electrodes CT1 may overlap the ground portion DD in the vertical direction (the Z direction).

Also, a plurality of vias VA may be provided. The plurality of vias VA may be positioned apart from each other in the first direction (the X direction) and the second direction (the Y direction). The plurality of vias VA may be arranged in the first direction (the X direction) and the second direction (the Y direction).

Referring to FIGS. 10 to 12, the image sensor 10 according to some embodiments may include an impurity region which is positioned inside the ground portion DD in the power region PR.

For example, as shown in FIGS. 10 and 11, the image sensor 10 may further include a first impurity region 161 which is positioned inside the ground portion DD in the power region PR and is electrically connected to the first contact electrode CT1. The first impurity region 161 may be buried in the ground portion DD. The lower surface of the first impurity region 161 may be positioned together with the lower surface of the ground portion DD on the same plane. The first impurity region 161 may be in contact with the first contact electrode CT1. In some embodiments, the first impurity region 161 may overlap the first connection pad 24 and at least some of the vias VA in the vertical direction (the Z direction); however, the present disclosure is not limited thereto. In some embodiments, the first impurity region 161 may contain an impurity of the first conductivity type. The first impurity region 161 may be doped into the same conductivity type as that of the first substrate 110. The first impurity region 161 may be doped with the impurity of the first conductivity type. For example, the impurity of the first conductivity type may be a p-type impurity such as aluminum (Al), boron (B), indium (In), and/or gallium (Ga). Accordingly, the first connection wiring structure CS1 may be stably connected to the ground portion DD through the first impurity region 161.

As another example, as shown in FIG. 12, the image sensor 10 may further include a second impurity region 162 which is positioned inside the ground portion DD in the power region PR and is electrically connected to the first contact electrode CT1. In some embodiments, the second impurity region 162 may contain an impurity of the second conductivity type. The second impurity region 162 may be doped into a conductivity type different from that of the first substrate 110. The second impurity region 162 may be doped with the impurity of the second conductivity type. For example, the impurity of the second conductivity type may include an n-type impurity such as phosphorus, arsenic, bismuth, and/or antimony. Accordingly, the first connection wiring structure CS1 may be stably connected to the ground portion DD through the second impurity region 162.

Referring to FIGS. 13 to 15, the image sensor 10 according to some embodiments may include the first impurity region 161 and the second impurity region 162 which are positioned inside the ground portion DD in the power region PR.

The first impurity region 161 and the second impurity region 162 may be positioned apart from each other. For example, as shown in FIG. 13, the first impurity region 161 and the second impurity region 162 may extend in the second direction (the Y direction) and be positioned apart from each other in the first direction (the X direction). In this case, between the first impurity region 161 and the second impurity region 162, an element isolation region 163 may be positioned. As another example, as shown in FIG. 15, the first impurity region 161 may surround the second impurity region 162. In this case, the first impurity region 161 and the second impurity region 162 may be spaced apart from each other by the element isolation region.

In some embodiments, the first impurity region 161 may overlap the first connection pad 24 and at least some of the vias VA in the vertical direction (the Z direction); however, the present disclosure is not limited thereto. Further, the second impurity region 162 may overlap the first connection pad 24 and at least some of the vias VA in the vertical direction (the Z direction); however, the present disclosure is not limited thereto.

In some embodiments, the first impurity region 161 and the second impurity region 162 may be doped with impurities having different conductivity types. For example, the first impurity region 161 may contain an impurity of the first conductivity type, and the second impurity region 162 may contain an impurity of the second conductivity type. Here, the first conductivity type may refer to a p-type, and the second conductivity type may refer to an n-type.

In some embodiments, each of the first impurity region 161 and the second impurity region 162 may be electrically connected to the first connection wiring structure CS1. For example, the first contact electrode CT1 may include a first sub contact electrode CT1a and a second sub contact electrode CT1b, and the first impurity region 161 may be electrically connected to the first sub contact electrode CT1a, and the second impurity region 162 may be electrically connected to the second sub contact electrode CT1b. The first impurity region 161 may be in contact with the first sub contact electrode CT1a, and the second impurity region 162 may be in contact with the second sub contact electrode CT1b. Accordingly, the first connection wiring structure CS1 may be stably connected to the ground portion DD through the first impurity region 161 and the second impurity region 162.

Referring to FIGS. 16 and 17, the image sensor 10 according to some embodiments may include the first impurity region 161 and the second impurity region 162 which are positioned inside the ground portion DD in the power region PR.

The second impurity region 162 may surround the first impurity region 161. In some embodiments, unlike in the embodiment of FIG. 15, the first impurity region 161 and the second impurity region 162 may be in contact with each other.

In some embodiments, the first impurity region 161 may be positioned inside the ground portion DD, and the second impurity region 162 may be positioned between the first impurity region 161 and the ground portion DD. In this case, the side surface and upper surface of the first impurity region 161 may be covered by the second impurity region 162. The lower surface of the first impurity region 161 may be positioned together with the lower surface of the second impurity region 162 and the lower surface of the ground portion DD on the same plane; however, the present disclosure is not limited thereto. In some embodiments, the first contact electrode CT1 may be electrically connected to the first impurity region 161. The first contact electrode CT1 may be in contact with the first impurity region 161.

In some embodiments, the first impurity region 161 may contain an impurity of the first conductivity type, and the second impurity region 162 may contain an impurity of the second conductivity type. Meanwhile, as described above, the ground portion DD may contain an impurity of the first conductivity type. Here, the first conductivity type may refer to a p-type, and the second conductivity type may refer to an n-type. Accordingly, the first impurity region 161, the second impurity region 162, and the ground portion DD may function as a PNP bipolar junction transistor (BTE) having a PNP structure. In this case, the first impurity region 161 may constitute the emitter of the PNP bipolar junction transistor (BTE), and the second impurity region 162 may constitute the base of the PNP bipolar junction transistor (BTE), and the ground portion DD may constitute the collector of the PNP bipolar junction transistor (BTE). In some embodiments, the second impurity region 162 may be floated such that the first connection wiring structure CS1 is stably connected to the ground portion DD.

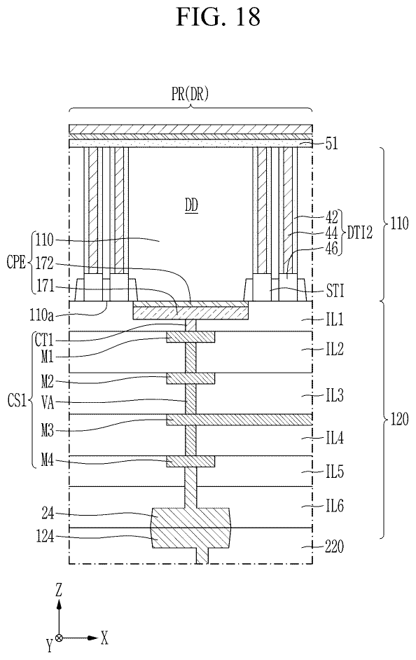

Referring to FIG. 18, the first connection wiring structure CS1 of the image sensor 10 according to some embodiments may further include a capacitor structure CPE which is positioned between the first contact electrode CT1 and the ground portion DD.

The first connection wiring structure CS1 may include a first electrode pattern 171 and a dielectric pattern 172 which are sequentially positioned on the first contact electrode CT1.

The first electrode pattern 171 may be positioned between the first contact electrode CT1 and the ground portion DD. The first electrode pattern 171 may overlap the ground portion DD and the first contact electrode CT1 in the vertical direction (the Z direction). The first electrode pattern 171 may be electrically connected to the first contact electrode CT1. The first electrode pattern 171 may be in contact with the first contact electrode CT1. The first electrode pattern 171 may contain a conductive material. At least a portion of the first electrode pattern 171 may overlap the element isolation pattern STI in the vertical direction (the Z direction); however, the present disclosure is not limited thereto.

The dielectric pattern 172 may be positioned between the ground portion DD and the first electrode pattern 171. The dielectric pattern 172 may be in contact with the ground portion DD and the first electrode pattern 171. At least a portion of the dielectric pattern 172 may overlap the element isolation pattern STI in the vertical direction (the Z direction); however, the present disclosure is not limited thereto. In some embodiments, the first electrode pattern 171, the dielectric pattern 172, and the ground portion DD may constitute the capacitor structure CPE. The capacitor structure CPE may function to store a signal and/or voltage received from the first connection wiring structure CS1.

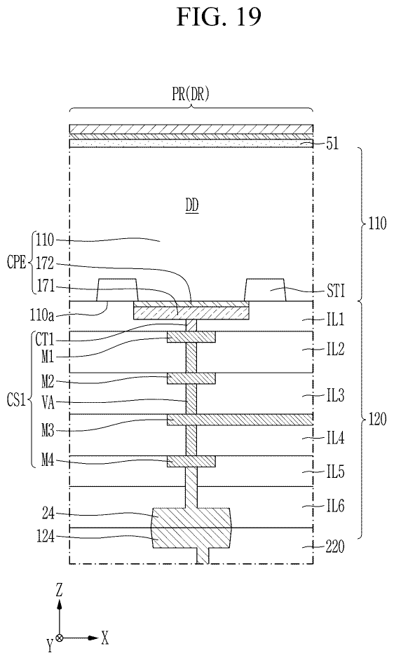

Referring to FIG. 19 together, the first connection wiring structure CS1 of the image sensor 10 according to some embodiments may further include the capacitor structure CPE which is positioned between the first contact electrode CT1 and the ground portion DD, and in the power region PR, the dummy isolation pattern DTI2 may be omitted.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While this disclosure has been described in connection with what is presently considered to be practical embodiments, it is to be understood that embodiments of inventive concepts are not limited to the disclosed embodiments. On the contrary, embodiments of inventive concepts are intended to cover various modifications and equivalent arrangements included within the spirit and scope of the appended claims.

### DESCRIPTION OF SYMBOLS

CH1: First Chip
CH2: Second Chip
110: First Substrate
120: Wiring Layer
CS1: First Connection Wiring Structure
CS2: Second Connection Wiring Structure
PD: Photoelectric Converter
FD: Floating Diffusion Zone
TG: Transfer Gate
MLL: Micro Lens Layer
APS: Pixel Area
OB: Optical Black Area
ER: Peripheral Area
DTI1: Pixel Isolation Pattern
DTI2: Dummy Isolation Pattern

What is claimed is:

1. An image sensor comprising:
a first chip including a first surface; and
a second chip on the first chip and including a second surface, the second surface of the second chip facing the first surface of the first chip, wherein
the first chip further includes a first connection pad on the first surface of the first chip,
the second chip further includes transistors and a second connection pad electrically connected to the transistors,
the second connection pad is on the second surface of the second chip,
the first connection pad and the second connection pad are electrically connected to each other,
the first chip further includes a substrate, a plurality of photoelectric converters in the substrate and corresponding to a plurality of pixels in a pixel area of the substrate, a ground portion in a peripheral area of the substrate, a dummy isolation pattern surrounding the ground portion and passing through the substrate, and a wiring layer,
the substrate includes a third surface and a fourth surface opposite each other,
the wiring layer includes a first connection wiring structure,
the first connection wiring structure is on the third surface of the substrate in the peripheral area and is electrically connected to the second connection pad, and
the first connection wiring structure includes a first contact electrode electrically connected to the ground portion in the peripheral area.

2. The image sensor of claim 1, wherein
the first connection wiring structure further includes a plurality of connection wiring lines and a plurality of vias connecting the plurality of connection wiring lines, and
the first contact electrode is between the plurality of connection wiring lines and the ground portion.

3. The image sensor of claim 1, wherein
the wiring layer further includes a second connection wiring structure,
the second connection wiring structure is electrically connected to the plurality of photoelectric converters in the pixel area, and
the second connection wiring structure is electrically connected to the first connection wiring structure.

4. The image sensor of claim 1, wherein
the first contact electrode is in contact with the ground portion.

5. The image sensor of claim 1, wherein
the peripheral area includes a power region positioned apart from the pixel area,
the power region is configured to receive a power voltage from the second chip, and
the first connection wiring structure is in the power region.

6. The image sensor of claim 5, wherein
the ground portion is in the power region, and
the first connection wiring structure overlaps the ground portion in a vertical direction.

7. The image sensor of claim 5, wherein
the peripheral area further includes a cap region,
the cap region is outside the pixel area,
the wiring layer includes a third connection wiring structure,
the third connection wiring structure is electrically connected to the substrate and the first connection wiring structure in the cap region, and
the third connection wiring structure includes a plurality of connection wiring lines, a plurality of vias connecting the plurality of connection wiring lines, a first electrode between the plurality of connection wiring lines and the substrate, and a dielectric layer between the first electrode and the substrate, and
the first electrode of the third connecting wiring structure is in contact with the third surface of the substrate.

8. The image sensor of claim 5, wherein
the peripheral area further includes a drive region configured to receive a driving signal for driving the plurality of photoelectric converters,
the wiring layer further includes a second connection wiring structure in the pixel area and a fourth connection wiring structure in the drive region,
the second connection wiring structure is electrically connected to the plurality of photoelectric converters,
the fourth connection wiring structure is configured to transfer the driving signal from the second chip to the second connection wiring structure,
the fourth connection wiring structure includes a second contact electrode, and
the second contact electrode is electrically connected to the substrate in the drive region.

9. The image sensor of claim 1, wherein
the ground portion of the substrate further includes a first ground impurity region, and
the first ground impurity region is connected to the first contact electrode.

10. The image sensor of claim 9, wherein
the substrate contains an impurity of a first conductivity type,
the plurality of photoelectric converters contain an impurity of a second conductivity type,
the second conductivity type is different from the first conductivity type, and
an impurity in the first ground impurity region is the first conductivity type.

11. The image sensor of claim 10, wherein
the ground portion of the substrate further includes a second ground impurity region,
the second ground impurity region surrounds the first ground impurity region,
an impurity in the second ground impurity region is the second conductivity type.

12. The image sensor of claim 1, further comprising:
an element isolation pattern in the substrate, wherein
the ground portion of the substrate further includes a first ground impurity region and a second ground impurity region on one side of the first ground impurity region,
the element isolation pattern is between the first ground impurity region and the second ground impurity region, and
each of the first ground impurity region and the second ground impurity region is connected to the first connection wiring structure.

13. The image sensor of claim 1, wherein
the first connection wiring structure further includes a contact gate electrode positioned between the first contact electrode and the ground portion, and
the first connection wiring includes a gate insulating layer between the ground portion and the contact gate electrode.

14. The image sensor of claim 1, wherein
the first surface of the first chip is in contact with the second surface of the second chip, and
the first connection pad is in contact with the second connection pad.

15. The image sensor of claim 1, wherein
the dummy isolation pattern completely surrounds the ground portion.

16. An image sensor comprising:
a substrate including a pixel area with a plurality of pixels, a power region outside the pixel area and configured to receive a power voltage, a plurality of photoelectric converters in the substrate and corresponding to the plurality of pixels, and a ground portion in the power region of the substrate;
a dummy isolation pattern surrounding the ground portion and passing through the substrate; and
a wiring layer on the substrate, wherein
the ground portion is electrically insulated from the plurality of photoelectric converters by the dummy isolation pattern,
the wiring layer further includes a first connection wiring structure and a second connection wiring structure,
the first connection wiring structure overlaps the ground portion in a vertical direction,
the first connection wiring structure is configured to receive a power voltage,
the second connection wiring structure overlaps the plurality of photoelectric converters in the vertical direction,
the second connection wiring structure electrically connects the substrate and the first connection wiring structure,
the first connection wiring structure includes a first contact electrode, and
the first contact electrode is electrically connected to the ground portion.

17. The image sensor of claim 16, wherein
the first connection wiring structure further includes a plurality of connection wiring lines and a plurality of vias connecting the plurality of connection wiring lines, and
the first contact electrode is between the plurality of connection wiring lines and the ground portion.

18. The image sensor of claim 16, wherein
the ground portion of the substrate includes a first ground impurity region,
the first ground impurity region is connected to the first contact electrode,
a conductivity type of the first ground impurity region is different from a conductivity type of the substrate.

19. The image sensor of claim 16, wherein
the first contact electrode is in contact with the ground portion.

20. An image sensor comprising:
a first chip including a first surface; and
a second chip on the first chip and including a second surface, the second surface of the second chip facing the first surface of the first chip, wherein
the first chip further includes a first connection pad on the first surface of the first chip,
the second chip further includes transistors and a second connection pad electrically connected to the transistors,
the second connection pad is on the second surface of the second chip,
the first connection pad and the second connection pad are electrically connected to each other,
the first chip further includes a substrate, a plurality of photoelectric converters in the substrate and corresponding to a plurality of pixel in a pixel area of the substrate, a pixel isolation pattern between the plurality of photoelectric converters, a ground portion in a peripheral area of the substrate, a dummy isolation pattern surrounding the ground portion and passing through the substrate, a wiring layer, a micro lens layer, and a first connection wiring structure,
the substrate includes a third surface and a fourth surface facing opposite each other,
the dummy isolation pattern is spaced apart from the pixel isolation pattern,
the micro lens layer is on the fourth surface of the substrate in the pixel area,
the first connection wiring structure is on the third surface of the substrate in the peripheral area and electrically connected to the second connection pad,
the first connection wiring structure includes a plurality of connection wiring lines, a plurality of vias connecting the plurality of connection wiring lines, and a first contact electrode between the plurality of connection wiring lines and the ground portion, and
the first connection wiring is electrically connected to the ground portion.
